(19) United States
(12) Patent Application Publication
(10) Pub. No.: US 2026/0121306 A1
(43) Pub. Date: Apr. 30, 2026

(54) ELECTRONIC DEVICE COMPRISING ANTENNA MODULE

(71) Applicant: LG ELECTRONICS INC., Seoul (KR)

(72) Inventors: Seungmin WOO, Seoul (KR); Yusuhk SUH, Seoul (KR); Dongik LEE, Seoul (KR)

(73) Assignee: LG ELECTRONICS INC., Seoul (KR)

(21) Appl. No.: 19/140,852

(22) PCT Filed: Dec. 22, 2022
(86) PCT No.: PCT/KR2022/021092

§ 371 Date: Jun. 18, 2025

(51) Int. Cl. H01Q 21/24; H01Q 1/38; H01Q 1/46; H01Q 21/06; H05K 1/02

(52) U.S. Cl. CPC H01Q 21/24; H01Q 1/38; H01Q 1/46; H01Q 21/06; H05K 1/0298

(57) ABSTRACT

Provided is an antenna module including a multi-layer substrate made of a plurality of dielectric materials and a conductive pattern. The multi-layer substrate comprises: a first layer; second layers formed on one side surface of the first layer; and third layers formed on the other side surface of the first layer. The conductive pattern includes: a first conductive pattern formed on the one side surface in a first region and a second region of the one side surface of the first layer to transmit and receive a signal; a second conductive pattern formed on a first sub-layer, which is one of the second layers; and a third conductive pattern formed on a second sub-layer, which is another layer of the second layers. The second conductive pattern and the third conductive pattern may be connected to each other through a first via hole.

### TECHNICAL FIELD

The present disclosure relates to an antenna module and an electronic device including the same. A particular implementation relates to an antenna module implemented as a dual-polarized antenna, and an electronic device including the antenna module.

### BACKGROUND ART

As functions of electronic devices diversify, an image display device such as a multimedia player having composite functions such as playback of music or video files, games, broadcasting reception, etc. may be implemented.

The image display device is an apparatus that plays image content, and receives an image from various sources and plays the image back. The image display device is implemented as various devices such as a personal computer (PC), a smartphone, a tablet PC, a laptop computer, a TV, etc. The image display apparatus such as a smart TV, etc. may provide an application for providing web content such as a web browser, etc.

A communication module including an antenna may be provided so that the electronic device such as the image display device may perform communication with a peripheral electronic device. Recently, as a display area of the image display device is enlarged, an arrangement space of the communication module including the antenna is reduced. Accordingly, there is an increasing need to arrange an antenna in a multi-layer circuit substrate on which a communication module is implemented.

Meanwhile, a WiFi wireless interface may be taken into account, as an interface for a communication service between electronic devices. When such a WiFi wireless interface is used, a millimeter wave (mmWave) band may be used for high-speed data transmission between the electronic devices. In particular, high-speed data transmission between electronic devices may be performed using a wireless interface such as an 802.11ay wireless interface.

In relation to this, an array antenna capable of operating in a mmWave band may be mounted in an antenna module. However, electronic components such as an antenna and a transceiver circuit arranged in such an antenna module are configured to be electrically connected to each other. To do so, the transceiver circuit may be operably coupled to the antenna module, and the antenna module may be configured as a multi-layer substrate.

As the multi-layer substrate of the antenna module is arranged to have a planar stacked structure, a constraint may occur when a vertically polarized antenna is implemented. In this regard, a length of the vertically polarized antenna may be configured to be greater than a height of the multi-layer substrate. Due to the constraint in the height of the multi-layer substrate, there is a problem in that antenna performance may deteriorate when the vertically polarized antenna is configured to have a small length.

In addition, when a dual-polarized antenna for a horizontally polarized antenna and a vertically polarized antenna is implemented, a combination structure between PCBs of different multi-layer substrates may be configured. In the combination structure between the PCBs of these different multi-layer substrates, lengths from respective feed lines to the vertically polarized antenna and the horizontally polarized antenna may be configured to be different from each other. Accordingly, performance differences between the vertically polarized antenna and the horizontally polarized antenna may occur, or a feed loss may increase in a mm Wave band due to an increase in lengths of the feed lines. Therefore, there is a problem such that an antenna gain of an antenna module having the combination structure between PCBs of different multi-layer substrates may be worsened.

### DISCLOSURE OF INVENTION

### Technical Problem

One object of this specification is to solve the aforementioned problems and other drawbacks. Another object of this specification is to provide an antenna module in which a dual-polarized antenna operating in a millimeter wave band is implemented, and an electronic device including the antenna module.

Another object of this specification is to implement an antenna performing radiation from one side of a printed circuit board (PCB) using a flexible printed circuit board (FPCB).

Another object of this specification is to provide a dual-polarized end-fire antenna such that a dual-polarized antenna operating as a horizontally polarized antenna and a vertically polarized antenna performs radiation through one side of a PCB.

Another object of this specification is to provide a vertically polarized antenna through an asymmetric dipole antenna arranged on an FPCB and a PCB.

Another object of this specification is to arrange an FPCB to be vertical to a PCB to implement vertical polarization even at a height of the PCB which is insufficient to implement the vertical polarization.

Another object of this specification is to implement one pole on an FPCB and another pole on a PCB as radiators to improve performance of vertical polarization, thereby increasing an area to enhance radiation performance.

Another object of this specification is to minimize an area occupied by antennas in a limited substrate region by arranging a vertically polarized antenna and a horizontally polarized antenna in an overlapping region.

Another object of this specification is to perform wireless communication with a peripheral electronic device by optimally arranging an antenna module on a lower portion of an electronic device.

### Solution to Problem

To achieve these and other advantages and in accordance with the purpose of an embodiment, as embodied and broadly described herein, there is provided an antenna module including a multi-layer substrate made of a plurality of dielectric materials and a conductive pattern. The multi-layer substrate includes a first layer; second layers arranged on one side surface of the first layer; and third layers arranged on another side surface of the first layer. The conductive pattern includes a first conductive pattern arranged on the one side surface in the first region and the second region of the one side surface of the first layer to transmit and receive a signal, a second conductive pattern arranged on a first sub-layer which is one layer among the second layers; and a third conductive pattern arranged on a second sub-layer which is another layer among the second layers. The second conductive pattern and the third conductive pattern are connected to each other through a first via hole.

According to an embodiment, the multi-layer substrate includes a first layer made of a flexible first material; second layers including a plurality of layers made of a rigid second material arranged on one side surface of the first layer; third layers including a plurality of layers made of the rigid second material arranged on another side surface of the first layer. The first layer includes a first region arranged in parallel with the second layers and the third layers, and a second region arranged to be vertical to the second layers and the third layers.

According to an embodiment, the first sub-layer may be arranged close to the one side surface of the first layer, and the second sub-layer may be arranged further apart from the one side surface of the first layer compared to the first sub-layer. A fourth conductive pattern arranged on a third sub-layer, which is one layer among the third layers, and a fifth conductive pattern arranged on a fourth sub-layer, which is another layer among the third layers, may be connected to each other through second via holes. The third sub-layer may be arranged close to the another side surface of the first layer, and the fourth sub-layer may be arranged further apart from the another side surface of the first layer compared to the third sub-layer.

According to an embodiment, a region of the first conductive pattern arranged in the first region of the one side surface of the first layer may be electrically connected to a first feed pattern arranged inside the substrate in one region of the first region. The second conductive pattern arranged on the first sub-layer, which is one layer among the second layers, may be electrically connected to a second feed pattern arranged inside the substrate in one region of the first sub-layer. One region of the fourth conductive pattern arranged on the third sub-layer, which is one layer among the third layers, may be connected to ground of the multi-layer substrate.

According to an embodiment, a space in the first conductive pattern arranged in the first region may be narrower than a space in the fourth conductive pattern connected to the ground of the multi-layer substrate.

According to an embodiment, the third conductive pattern arranged on the second sub-layer, which is another layer among the second layers, may include a first sub-pattern, a second sub-pattern, and a third sub-pattern. The first sub-pattern may be connected to the second conductive pattern through the first via hole. One region of the third sub-pattern may be connected to the ground of the substrate. The first sub-pattern and the third sub-pattern may be connected to each other by the second sub-pattern.

According to an embodiment, a length of the second sub-pattern may be configured to be greater than a space in a gap between the first sub-pattern and the third sub-pattern.

According to an embodiment, the second sub-pattern may include pattern regions extending, toward both sides, from two portions connected to a pattern region between the first sub-pattern and the third sub-pattern.

According to an embodiment, the first conductive pattern located in the first region may be arranged in a middle region between the first sub-pattern and the third sub-pattern.

According to an embodiment, the fourth conductive pattern may include a fourth sub-pattern connected to one region of the ground of the multi-layer substrate and a fifth sub-pattern connected to the second via holes. A space in the fourth sub-pattern, which is a part of the fourth conductive pattern, may be narrower than a space in the fifth conductive pattern arranged in the fourth sub-layer among the third layers.

According to an embodiment, a length of the fifth conductive pattern may be shorter than a length of the fourth sub-pattern of the fourth conductive pattern.

According to an embodiment, one end region of the fifth conductive pattern may be configured to be electrically connected to the fifth sub-pattern through a plurality of rows of a plurality of via holes.

According to an embodiment, the first conductive pattern, the fourth conductive pattern, the fifth conductive pattern, and the plurality of via holes may operate as antenna elements having horizontal polarization. The second conductive pattern and the third conductive pattern operate as antenna elements having horizontal polarization.

According to an embodiment, a first height of the third conductive pattern may be configured to be within a predetermined range with reference to 1 mm. A second height between the fourth conductive pattern and the fifth conductive pattern of a via structure implemented by the plurality of via holes may be configured to be within a predetermined range with reference to 0.3 mm.

According to an embodiment, the fourth sub-pattern of the fourth conductive pattern may be configured to have a first width, and the fifth sub-pattern of the fourth conductive pattern may be configured to have a second width greater than the first width. The via structure may include a plurality of via holes arranged to be spaced apart from each other by a predetermined space to connect the fourth sub-pattern to the fifth conductive pattern in a first axial direction. The second width of the fifth sub-pattern may be configured to be in a range between 0.2 mm and 1.0 mm.

According to an embodiment, the antenna elements may be arranged in plurality in the first axial direction to constitute an array antenna. A first horizontally polarized antenna element to a fourth horizontally polarized antenna element of the array antenna may be configured to radiate a beamformed first wireless signal having horizontal polarization in the first axial direction. A first vertically polarized antenna element to a fourth vertically polarized antenna element of the array antenna may be configured to radiate a beamformed second wireless signal having vertical polarization in the first axial direction.

According to an embodiment, the antenna module may further include a shield can arranged on a ground pattern in an upper portion of a ground wall arranged in an inner region of a printed circuit board (PCB) of the multi-layer substrate. A distance d from the shield can to the third conductive pattern arranged on a flexible printed circuit board (FPCB) is arranged in a range of (0.17+n)*λ₀ <d<(0.33+n)*λ₀.

According to an embodiment, an electronic device according to another embodiment includes a metal frame constituting a side region of the electronic device; a dielectric case arranged on one side of the metal frame; and an antenna module arranged in an inner region of the dielectric case, arranged to face an inner surface of the dielectric case, and including a multi-layer substrate made of a plurality of dielectric materials and a conductive pattern. The multi-layer substrate includes a first layer; second layers arranged on one side surface of the first layer; and third layers arranged on another side surface of the first layer. The conductive pattern includes a first conductive pattern arranged on the one side surface in the first region and the second region of the one side surface of the first layer to transmit and receive a signal, a second conductive pattern arranged on a first sub-layer which is one layer among the second layers; and a third conductive pattern arranged on a second sub-layer which is another layer among the second layers. The second conductive pattern and the third conductive pattern may be connected to each other through a first via hole.

According to an embodiment, the multi-layer substrate includes: a first layer made of a flexible first material; second layers including a plurality of layers made of a rigid second material arranged on one side surface of the first layer; and third layers including a plurality of layers made of the rigid second material arranged on another side surface of the first layer. The first layer includes a first region arranged in parallel with the second layers and the third layers, and a second region arranged to be vertical to the second layers and the third layers.

According to an embodiment, the first sub-layer may be arranged to be close to the one side surface of the first layer, and the second sub-layer may be arranged further apart from the one side surface of the first layer compared to the first sub-layer. A fourth conductive pattern arranged on a third sub-layer, which is one layer among the third layers, and a fifth conductive pattern arranged on a fourth sub-layer, which is another layer among the third layers, may be connected to each other through second via holes. The third sub-layer may be arranged close to the another side surface of the first layer, and the fourth sub-layer may be arranged further apart from the another side surface of the first layer compared to the third sub-layer.

According to an embodiment, a region of the first conductive pattern arranged in the first region of the one side surface of the first layer may be electrically connected to a first feed pattern arranged inside the substrate in one region of the first region. The second conductive pattern arranged on the first sub-layer, which is one layer among the second layers, may be electrically connected to a second feed pattern arranged inside the substrate in one region of the first sub-layer. One region of the fourth conductive pattern arranged on the third sub-layer, which is one layer among the third layers, may be connected to ground of the multi-layer substrate.

According to an embodiment, a space in the first conductive pattern arranged in the first region may be narrower than a space in the fourth conductive pattern connected to the ground of the multi-layer substrate.

According to an embodiment, the third conductive pattern arranged on the second sub-layer, which is another layer among the second layers, may include a first sub-pattern, a second sub-pattern, and a third sub-pattern. The first sub-pattern may be connected to the second sub-pattern through the first via hole. One region of the third sub-pattern may be connected to the ground of the substrate. The first sub-pattern and the third sub-pattern may be connected to each other by the second sub-pattern.

According to an embodiment, a length of the second sub-pattern may be configured to be greater than a space in a gap between the first sub-pattern and the third sub-pattern.

### Advantageous Effects of Invention

Hereinafter, technical effects of an antenna module implemented as a dual-polarized antenna according to this specification and an electronic device including the antenna module are described.

According to an embodiment, an antenna module in which a dual-polarized antenna operating in a millimeter wave band is implemented, and an electronic device including the antenna module may be provided.

According to an embodiment, an antenna may be implemented on one side of a printed circuit board (PCB) to perform radiation through a conductive pattern of a flexible printed circuit board (FPCB) and a via structure and a conductive pattern implemented on one side of the PCB.

According to an embodiment, a dual-polarized end-fire antenna may be provided such that a dual-polarized antenna operating as a horizontally polarized antenna and a vertically polarized antenna performs radiation through one side of a PCB.

According to an embodiment, a vertically polarized antenna may be provided through an asymmetrical dipole antenna constituted by an upper-end pole and a lower-end pole arranged on an FPCB and a PCB, respectively.

According to an embodiment, vertical polarization may be implemented even at a height of a PCB which is insufficient to implement the vertical polarization by arranging an FPCB vertically to the PCB and through a conductive pattern of the FPCB and a conductive pattern and a vertical via of the PCB.

According to an embodiment, radiation performance may be enhanced by increasing an area by implementing one pole on an FPCB and another pole on a PCB as radiators to thereby improve performance of vertical polarization.

According to an embodiment, an area occupied by antennas in a limited substrate region may be minimized by arranging a vertically polarized antenna and a horizontally polarized antenna in an overlapping region.

According to an embodiment, wireless communication may be performed with a peripheral electronic device by optimally arranging an antenna module on a lower portion of an electronic device.

Further scope of applicability of this specification will become apparent from the following detailed description. It should be understood, however, that the detailed description and specific examples, such as the preferred embodiment of the disclosure, are given by way of illustration only, since various changes and modifications within the spirit and scope of the disclosure will be apparent to those skilled in the art.

### BRIEF DESCRIPTION OF DRAWINGS

FIG. 1 is a diagram schematically illustrating an example of a whole wireless audio-video (AV) system including an image display device according to one embodiment of this specification.

FIG. 2 illustrates a detailed configuration of electronic devices that support a wireless interface according to this specification.

FIG. 3A illustrates a request-to-send frame (RTS) and a clear-to-send (CTS) frame according to this specification.

FIG. 3B illustrates a block diagram of a communication system 400 according to an example of this specification.

FIG. 4 illustrates an electronic device in which a plurality of antenna modules and a plurality of transceiver circuit modules are arranged, according to an embodiment.

FIG. 5A illustrates a configuration in which a multi-layer circuit substrate on which an array antenna module is arranged is connected to a radio frequency integrated chip (RFIC), in relation to this specification.

FIG. 5B is a conceptual diagram illustrating antenna structures having different radiation directions.

FIG. 5C illustrates a combination structure between a multi-layer substrate and a main substrate according to embodiments.

FIG. 6 is a conceptual diagram illustrating a plurality of communication modules arranged in a lower portion of an image display device, a configuration of the corresponding communication modules, and communication performed between the communication modules and other communication modules arranged in a front direction.

FIG. 7A is a perspective view of a structure in which a printed circuit board (PCB) and a flexible printed circuit board (FPCB) each having antenna elements arranged thereon are connected to each other.

FIG. 7B is a side view of the structure in which the PCB and FPCB of FIG. 7A are connected to each other.

FIG. 7C illustrates a structure of a dual-polarized antenna excluding a dielectric region of the PCB.

FIG. 8 illustrates various configurations in which a PCB having a feed pattern and a ground pattern placed thereon and an FPCB are connected to each other.

FIG. 9 illustrates structures of a vertically polarized antenna and a horizontally polarized antenna according to embodiments.

FIG. 10A is a front view of a structure in which a vertically polarized antenna and a vertically polarized antenna are arranged in corresponding regions of different layers in the dual-polarized antenna structure of FIGS. 7A to 7C.

FIG. 10B illustrates a vertically polarized antenna structure constituted by an upper-end pole and a lower-end pole in the dual-polarized antenna structure of FIGS. 7A to 7C.

FIG. 11 shows a comparison between current distribution diagrams in correspondence with coupling between antennas according to a change in a width of a third conductive pattern of a vertically polarized antenna.

FIG. 12 shows reflection coefficient characteristics of a horizontally polarized antenna according to a width of a third conductive pattern, which is a lower-end pole, in an antenna module implemented as a dual-polarized antenna.

FIG. 13A shows a current distribution diagram in a case when a width of a first conductive pattern of a vertically polarized antenna is greater than a space between a first sub-pattern and a third sub-pattern of a horizontally polarized antenna.

FIG. 13B shows an impedance change presented on a Smith chart according to a change in a width of a first conductive pattern of a vertically polarized antenna.

FIG. 14 illustrates a structure in which a horizontally polarized antenna is capable of being placed in an upper region or a lower region of a PCB of an antenna module.

FIG. 15A shows a comparison between current distribution diagrams according to structures in which a horizontally polarized antenna is arranged.

FIG. 15B shows reflection coefficient characteristics according to structures in which a horizontally polarized antenna is arranged.

FIG. 16A illustrates an antenna module implemented as a dual-polarized array antenna according to an embodiment.

FIG. 16B illustrates a structure in which a shield can is arranged on top of a PCB of the antenna module of FIG. 16A.

FIG. 17A is a front view of an array antenna module in which the shield can of FIG. 16B is arranged.

FIG. 17B is a side view of the array antenna module in which the shield can of FIG. 17A is arranged.

FIG. 18 illustrates an electronic device having an antenna module arranged in a dielectric case according to this specification.

FIG. 19A illustrates a structure in which an antenna module constituted by a plurality of array antennas is arranged in an electronic device.

FIG. 19B is an enlarged view of the plurality of array antenna modules of FIG. 19A.

FIG. 20 illustrates an antenna module combined in varying combination structures at a particular position in an electronic device according to embodiments.

### MODE FOR THE INVENTION

Hereinafter, embodiments disclosed herein will be described in detail with reference to the accompanying drawings, and the same or similar elements are designated with the same numeral references, regardless of the numerals in the drawings, and their redundant description will be omitted. Suffixes “module” and “unit” used for components used in the following description are merely intended for easy description of this specification, and each suffix itself is not intended to give any special meaning or function. In describing the embodiments disclosed herein, moreover, the detailed description will be omitted when specific description for publicly known technologies to which the disclosure pertains is judged to obscure the gist of this specification. The accompanying drawings are used to help easily understand the technical idea of this specification and it should be understood that the idea of this specification is not limited by the accompanying drawings. The idea of this specification should be construed to extend to any alterations, equivalents and substitutes besides the accompanying drawings.

It will be understood that although the terms first, second, etc. may be used herein to describe various elements, these elements should not be limited by these terms. These terms are generally only used to distinguish one element from another.

It will be understood that when an element is referred to as being “connected” or “coupled” to another element, the element may be directly connected or coupled to the another element, or intervening elements may also be present. In contrast, when an element is referred to as being “directly connected with” another element, there are no intervening elements present.

A singular representation may include a plural representation unless it represents a definitely different meaning from the context.

Terms such as “include” or “has” as used herein should be understood that they are intended to indicate the existence of a feature, a number, a step, an element, a component, or a combination thereof disclosed in this specification, and it may also be understood that a possibility of presence or addition of one or more other features, numbers, steps, elements, components, or combinations thereof are not excluded in advance.

An electronic device described herein may include a mobile phone, a smartphone, a laptop computer, a digital broadcasting terminal, a personal digital assistant (PDA), a portable multimedia player (PMP), a navigation system, a slate personal computer (PC), a tablet PC, an ultrabook, a wearable device, (e.g., a smartwatch, smart glasses, a head mounted display (HMD)), or the like.

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, digital signage, and the like.

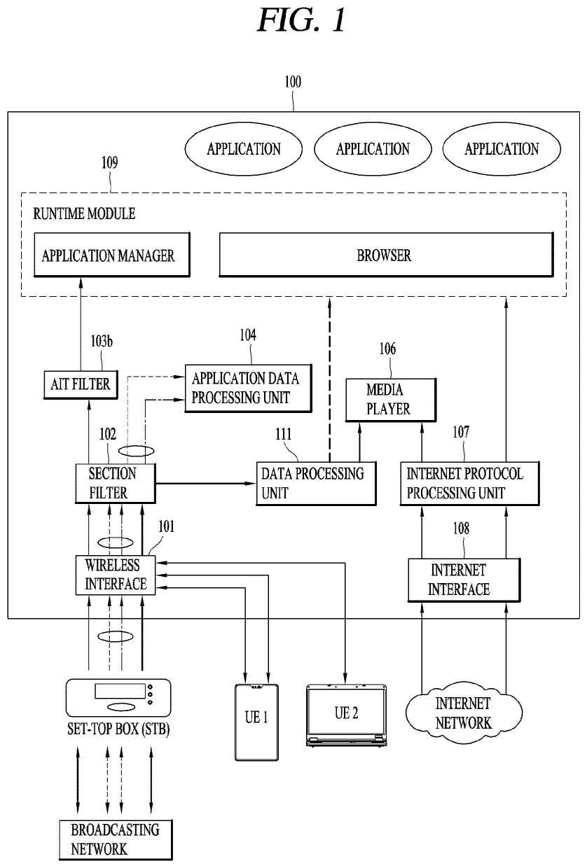

FIG. 1 is a diagram schematically illustrating an example of a whole wireless audio-video (AV) system including an image display device according to one embodiment of this specification.

As illustrated in FIG. 1, an image display device 100 according to another embodiment of the present disclosure is connected to the wireless AV system (or a broadcasting network) and an Internet network. The image display device 100 may be, for example, a network TV, a smart TV, a hybrid broadcast broadband TV (HBBTV), or the like.

The image display device 100 may be wirelessly connected to the wireless AV system (or the broadcasting network) via a wireless interface or wirelessly or wiredly connected to the Internet network via an Internet interface. In relation to this, the image display device 100 may be configured to be connected to a server or another electronic device via a wireless communication system. As an example, the image display device 100 needs to provide an 802.111ay communication service operating in a millimeter wave (mmWave) band to transmit or receive large-capacity data at a high speed.

The mm Wave band may be any frequency band in a range of 10 GHz to 300 GHz. In this disclosure, the mm Wave band may include an 802.11ay band of a 60 GHz band. In addition, the mm Wave band may include a 5G frequency band of a 28 GHz band or the 802.11ay band of the 60 GHz band. The 5G frequency band may be set to about 24 to 43 GHz band and the 802.11ay band may be set to 57 to 70 GHz or 57 to 63 GHz band, but are not limited thereto.

Meanwhile, the image display device 100 may wirelessly transmit or receive data to/from an electronic device in a periphery of the image display device 100, e.g., a set-top box or another electronic device via the wireless interface. As an example, the image display device 100 may transmit or receive wireless AV data to/from a set-top box or another electronic device, e.g., a mobile terminal arranged in front of or below the image display device.

The image display device 100 includes, for example, a wireless interface 101b, a section filter 102b, an application information table (AIT) filter 103b, an application data processing unit 104b, a data processing unit 111b, a media player 106b, an Internet protocol processing unit 107b, an Internet interface 108b, and a runtime module 109b.

Through the broadcast interface 101b, application information table (AIT) data, real-time broadcast content, application data, and a stream event are received. Meanwhile, the real-time broadcast content may be referred to as linear audio/video (A/V) content.

The section filter 102b performs section filtering on four types of data received through the wireless interface 101b to transmit the AIT data to the AIT filter 103b, the linear A/V content to the data processing unit 111b, and the stream events and the application data to the application data processing unit 104b.

Meanwhile, the non-linear A/V content and the application data are received through the Internet interface 108b. The non-linear A/V content may be, for example, a content on demand (COD) application. The non-linear A/V content is transmitted to the media player 106b, and the application data is transmitted to the runtime module 109b.

Further, the runtime module 109b includes, for example, an application manager and a browser as illustrated in FIG. 1. The application manager controls a life cycle of an interactive application using, for example, the AIT data. In addition, the browser performs, for example, a function of displaying and processing the interactive application.

Hereinafter, a communication module having an antenna for providing a wireless interface in an electronic device such as the above-described image display device is described in detail. In relation to this, the wireless interface for communication between electronic devices may be a WiFi wireless interface, but is not limited thereto. As an example, a wireless interface supporting an 802.11ay standard may be provided for high-speed data transmission between electronic devices.

The 802.11ay standard is a subsequent standard for increasing a throughput of an 802.11ad standard to 20 Gbps or greater. An electronic device supporting the 802.11ay wireless interface may be configured to use a frequency band of about 57 to 64 GHz. The 802.11ay wireless interface may be configured to provide backward compatibility for an 802.11ad wireless interface. Meanwhile, the electronic device providing the 802.11ay wireless interface may be configured to provide coexistence with a legacy device using the same band.

In relation to a wireless environment for the 802.11ay standard, a configuration may be such that a coverage of 10 meters or longer is provided in an indoor environment, and a coverage of 100 meters or longer is provided in an outdoor environment with a line of sight (LOS) channel condition.

The electronic device supporting the 802.11ay wireless interface may be configured to provide visual reality (VR) headset connectivity, support server backups, and support cloud applications that need low latency.

An ultra short range (USR) communication scenario, i.e., a near field communication scenario which is a use case of the 802.11ay wireless interface is a model for fast large-capacity data exchange between two terminals. The USR communication scenario may be configured to require low power consumption of less than 400 mW, while providing a fast link setup within 100 msec, transaction time within 1 second, and a 10 Gbps data rate at a very close distance of less than 10 cm.

As the use case of the 802.11ay wireless interface, an 8K UHD wireless transfer at smart home usage model may be taken into account. In the smart home usage model, a wireless interface between a source device and a sync device may be taken into consideration to stream 8K UHD content at home. In relation to this, the source device may be one of a set-top box, a Blue-ray player, a tablet PC, and a smart phone and the sink device may be one of a smart TV and a display device, but are not limited thereto. In relation to this, the wireless interface may be configured to transmit uncompressed 8K UHD streaming data (60 fps, 24 bits per pixel, at least 4:2:2) with a coverage of less than 5 m between the source device and the sink device. To do so, the wireless interface may be configured such that data is transmitted between electronic devices at a speed of at least 28 Gbps.

In order to provide such a wireless interface, embodiments related to an array antenna operating in a mm Wave band and an electronic device including the array antenna is described with reference to the accompanying drawings. It will be apparent to those skilled in the art that this specification may be embodied in other specific forms without departing from the spirit or essential characteristics thereof.

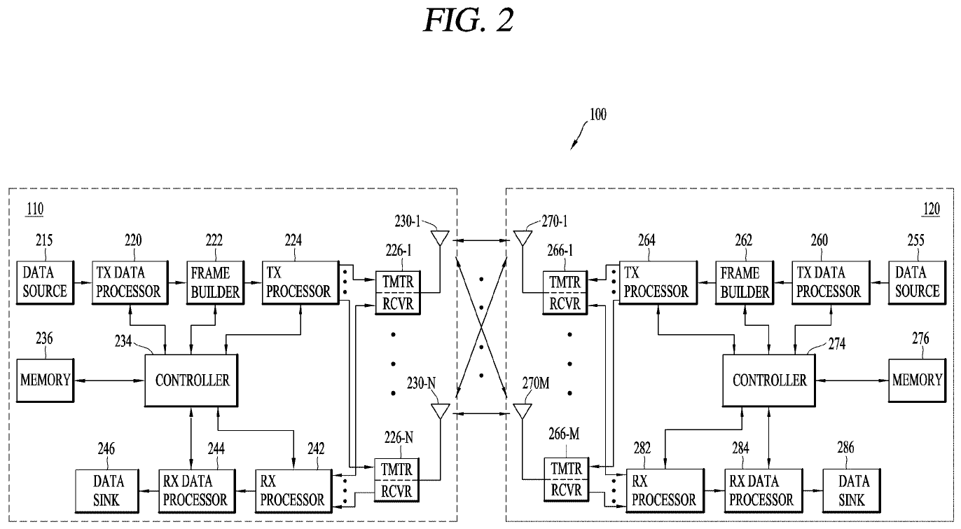

FIG. 2 illustrates a detailed configuration of electronic devices that support a wireless interface according to this specification. FIG. 2 illustrates a block diagram of an access point 110 (generally, a first wireless node) and an access terminal 120 (generally, a second wireless node) in a wireless communication system. The access point 110 is a transmitting entity for downlink transmission and a receiving entity for uplink transmission. The access terminal 120 is a transmitting entity for uplink transmission and a receiving entity for downlink transmission. As used herein, the “transmitting entity” is an independently operating apparatus or device capable of transmitting data through a wireless channel, and the “receiving entity” is an independently operating apparatus or device capable of receiving data through a wireless channel.

Referring to FIGS. 1 and 2, the set-top box (STB) of FIG. 1 may be the access point 110, and an electronic device 100 of FIG. 1 may be the access terminal 120, but are not limited thereto. Accordingly, it should be understood that the access point 110 may alternatively be an access terminal, and the access terminal 120 may alternatively be an access point.

To transmit data, the access point 110 includes a transmission data processor 220, a frame builder 222, a transmission processor 224, a plurality of transceivers 226-1 to 226-N, and a plurality of antennas 230-1 to 230-N. The access point 110 also includes a controller 234 configured to control operations of the access point 110.

To transmit data, the access point 110 includes a transmission data processor 220, a frame builder 222, a transmission processor 224, a plurality of transceivers 226-1 to 226-N, and a plurality of antennas 230-1 to 230-N. The access point 110 also includes a controller 234 configured to control operations of the access point 110.

During operation, the transmission data processor 220 receives data (e.g., data bits) from a data source 215, and processes the data for transmission. For example, the transmission data processor 220 may encode data (e.g., data bits) into encoded data, and modulate the encoded data into data symbols. The transmission data processor 220 may support different modulation and coding schemes (MCSs). For example, the transmission data processor 220 may the encode data at any one of a plurality of different coding rates (e.g., using low-density parity check (LDPC) encoding). In addition, the transmission data processor 220 may modulate the encoded data using any one of a plurality of different modulation schemes including, but not limited to, BPSK, QPSK, 16QAM, 64QAM, 64APSK, 128APSK, 256QAM, and 256APSK.

The controller 234 may transmit, to the transmission data processor 220, a command for specifying an MCS to be used (e.g., based on channel conditions for downlink transmission). The transmission data processor 220 may encode and modulate the data received from the data source 215 according to the specified MCS. It needs to be recognized that the transmission data processor 220 may perform additional processing on the data, such as data scrambling and/or other processing. The transmission data processor 220 outputs the data symbols to the frame builder 222.

The frame builder 222 builds a frame (also referred to as a packet) and inserts the data symbols into a data payload of the frame. The frame may include a preamble, a header, and a data payload The preamble may include a short training field (STF) sequence and a channel estimation (CE) sequence to assist the access terminal 120 in receiving the frame. The header may include information regarding data in a payload, such as a length of the data and an MCS used to encode and modulate the data. Based on this information, the access terminal 120 may demodulate and decode the data. The data in the payload may be partitioned among a plurality of blocks, and each block may contain a part of the data and a guard interval (GI) to assist the receiver in phase tracking. The frame builder 222 outputs the frame to the transmission processor 224.

The transmission processor 224 processes the frame for transmission on downlink. For example, the transmission processor 224 may support different transmission modes, e.g., an orthogonal frequency-division multiplexing (OFDM) transmission mode and a single-carrier (SC) transmission mode. In this example, the controller 234 may transmit, to the transmission processor 224, a command for specifying a transmission mode to be used, and the transmission processor 224 may process the frame for transmission according to the specified transmission mode. The transmission processor 224 may apply a spectrum mask to the frame so that a frequency configuration of a downlink signal complies with particular spectrum requirements.

The transmission processor 224 may support multiple-input-multiple-output (MIMO) transmission. In these aspects, the access point 110 may include a plurality of antennas 230-1 to 230-N and a plurality of transceivers 226-1 to 226-N (e.g., one for each antenna). The transmission processor 224 may perform spatial processing on incoming frames and provide a plurality of transmission frame streams to a plurality of antennas. The transceivers 226-1 to 226-N receive and process (e.g., convert to analog, amplify, filter, and frequency up-convert) each of the transmission frame streams to generate transmission signals for transmission through the antennas 230-1 to 230-N.

To transmit data, the access terminal 120 includes a transmission data processor 260, a frame builder 262, a transmission processor 264, a plurality of transceivers 266-1 to 266-M, and a plurality of antennas 270-1 to 270-M (e.g., one antenna per transceiver). The access terminal 120 may transmit data to the access point 110 on uplink and/or transmit the data to another access terminal (e.g., for peer-to-peer communication). The access terminal 120 also includes a controller 274 for controlling operations of the access terminal 120 The transceivers 266-1 to 266-M receive and process (e.g., convert to analog, amplify, filter, and frequency up-convert) an output from the transmission processor 264 for transmission via one or more of the antennas 270-1 to 270-M. For example, the transceiver 266 may up-convert the output from the transmission processor 264 into a transmission signal having a frequency in a 60 GHz band. Accordingly, the antenna module described herein may be configured to perform a beamforming operation in the 60 GHz band, for example, in a band of about 57 to 63 GHz. In addition, the antenna module may be configured to support MIMO transmission while performing beamforming in the 60 GHz band.

In relation to this, the antennas 270-1 to 270-M and the transceivers 266-1 to 266-M may be implemented in an integrated form on a multi-layer circuit substrate. To do so, among the antennas 270-1 to 270-M, an antenna that operates with vertical polarization may be vertically arranged inside the multi-layer circuit substrate.

To receive data, the access point 110 includes a reception processor 242 and a reception data processor 244. During operation, the transceivers 226-1 to 226-N receive a signal (e.g., from the access terminal 120) and spatially process (e.g., frequency down-convert, amplify, filter, and digitally convert) the received signal.

The reception processor 242 receives outputs from the transceivers 226-1 through 226-N and processes the outputs to recover data symbols. For example, the access point 110 may receive data from a frame (e.g., from the access terminal 120). In this example, the reception processor 242 may detect a start of the frame using a short training field (STF) sequence in a preamble of the frame. The reception processor 242 may also use the STF for automatic gain control (AGC) adjustment. The reception processor 242 may also perform channel estimation (e.g., using a channel estimation (CE) sequence in the preamble of the frame), and perform channel equalization on the received signal based on the channel estimation.

The reception data processor 244 receives the data symbols from the reception processor 242 and an indication of a corresponding MSC scheme from the controller 234. The reception data processor 244 demodulates and decodes the data symbols, recovers the data according to the indicated MSC scheme, and stores and/or outputs the recovered data (e.g., data bits) to a data sink 246 for additional processing.

The access terminal 120 may transmit the data using an orthogonal frequency-division multiplexing (OFDM) transmission mode or a single-carrier (SC) transmission mode. In this case, the reception processor 242 may process the received signal according to a selected transmission mode. In addition, as described above, the transmission processor 264 may support MIMO transmission. In this case, the access point 110 includes the plurality of antennas 230-1 to 230-N and the plurality of transceivers 226-1 to 226-N (e.g., one for each antenna). Accordingly, the antenna module described herein may be configured to perform a beamforming operation in the 60 GHz band, for example, in a band of about 57 to 63 GHz. In addition, the antenna module may be configured to support MIMO transmission while performing beamforming in the 60 GHz band.

In relation to this, the antennas 230-1 to 230-M and the transceivers 226-1 to 226-M may be implemented in an integrated form on a multi-layer circuit substrate. To do so, among the antennas 230-1 to 230-M, an antenna that operates with vertical polarization may be vertically arranged inside the multi-layer circuit substrate.

Meanwhile, each transceiver receives and processes (e.g., frequency down-converts, amplifies, filters, and digitally converts) a signal from each antenna. The reception processor 242 may perform spatial processing on the outputs from the transceivers 226-1 to 226-N to recover the data symbols.

The access point 110 also includes a memory 236 coupled to the controller 234. The memory 236 may store commands that, when executed by the controller 234, cause the controller 234 to perform one or more of the operations described herein. Similarly, the access terminal 120 also includes a memory 276 coupled to the controller 274. The memory 276 may store commands that, when executed by the controller 274, cause the controller 274 to perform one or more of the operations described herein.

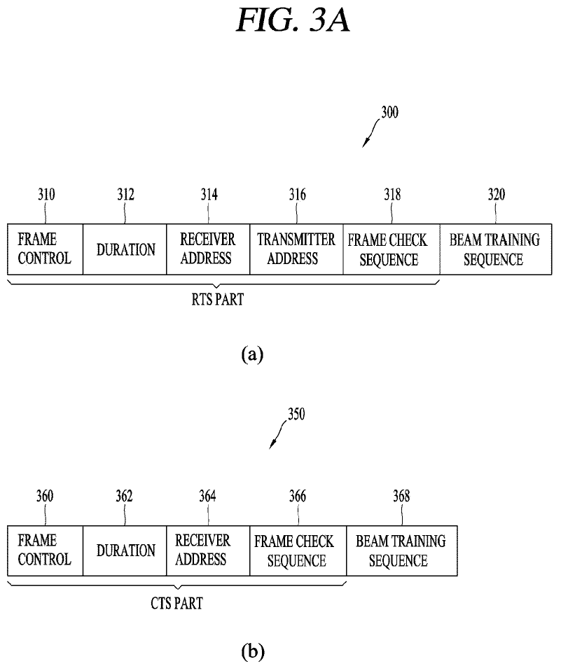

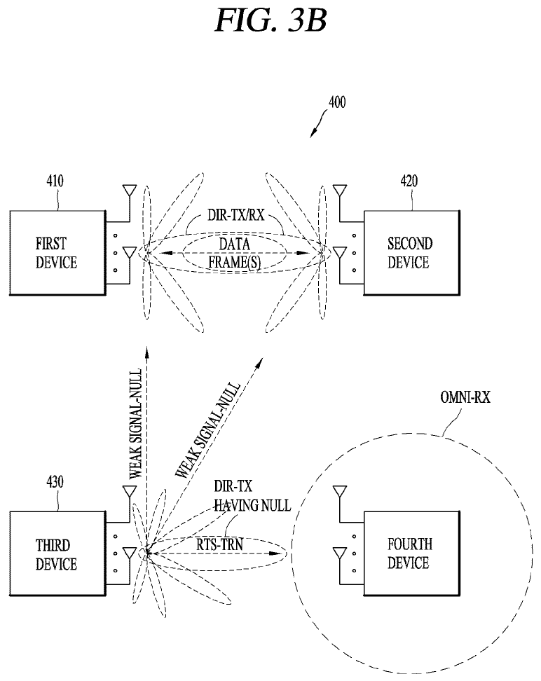

Meanwhile, an electronic device supporting the 802.11ay wireless interface described herein determines whether a communication medium may be used to communicate with another electronic device. To do so, the electronic device transmits a request-to-send (RTS)-TRN frame including an RTS part and a first beam training sequence. In relation to this, FIG. 3A illustrates a request-to-send frame (RTS) and a clear-to-send (CTS) frame according to this specification. In relation to this, a transmission device may use the RTA frame to determine whether a communication medium may be used to transmit one or more data frames to a destination device. In a response to receiving the RTS frame, the destination device transmits the CTS frame back to the transmission device when the communication medium may be used. In a response to receiving the CTS frame, the transmission device transmits one or more data frames to the destination device. In a response to successfully receiving the one or more data frames, the destination device transmits one or more acknowledgment (“ACK”) frames to the transmission device.

Referring to (a) of FIG. 3A, a frame 300 includes the RTS part including a frame control field 310, a duration field 312, a receiver address field 314, a transmitter address field 316, and a frame check sequence field 318. To improve communication and reduce interference, the frame 300 further includes a beam training sequence field 320 for configuring respective antennas of the destination device and one or more neighboring devices.

Referring to (b) of FIG. 3A, a CTS frame 350 includes a CTS part including a frame control field 360, a duration field 362, a receiver address field 364, and a frame check sequence field 366. To improve communication and reduce interference, the frame 350 further includes a beam training sequence field 368 for configuring respective antennas of the transmission device and one or more neighboring devices.

The beam training sequence fields 320 and 368 may conform to a training (TRN) sequence according to the IEEE 802.11ad or 802.11ay standard. The transmission device may use the beam training sequence field 368 to configure an antenna of the transmission device for directional transmission to the destination device. Meanwhile, transmission devices may use the beam training sequence field to configure respective antennas of the transmission devices to prevent transmission interference at the destination device. In this case, the beam training sequence field may be used to configure the respective antennas of the transmission devices to generate an antenna radiation pattern with nulls targeting the destination device.

Accordingly, electronic devices supporting the 802.11ay wireless interface may generate an initial beam to have a low interference level with each other, using a beamforming pattern determined according to a beam training sequence. In relation to this, FIG. 3B illustrates a block diagram of a communication system 400 according to an example of this specification. As illustrated in FIG. 3B, first and second devices 410 and 420 may improve communication performance by matching directions of main beams with each other. To reduce interference with a third device 430, the first and second devices 410 and 420 may create a signal-null having a weak signal strength in a particular direction.

In relation to the generation of the main beams and the signal-null, a plurality of electronic devices described herein may be configured to perform beamforming through an array antenna. Referring to FIG. 3B, some of the electronic devices may be configured to communicate with an array antenna of another electronic device through a single antenna. In relation to this, when communication is performed through a single antenna, a beam pattern is generated as an omnidirectional pattern.

Referring to FIG. 3B, it is shown that the first to third devices 410 to 430 perform beamforming and a fourth device 440 does not perform beamforming. However, performance of beamforming is not limited thereto. Accordingly, three of the first to fourth devices 410 may be configured to perform beamforming, and the other may be configured not to perform beamforming.

As another example, only one of the first to fourth devices 410 may be configured to perform beamforming, and the other three devices may be configured not to perform beamforming. As another example, two of the first to fourth devices 410 may be configured to perform beamforming but the other two may be configured not to perform beamforming. As another example, all of the first to fourth devices 410 may be configured to perform beamforming.

Referring to FIGS. 3A and 3B, the first device 410 determines that the first device 410 is an intended receiving device for the CTS-TRN frame 350, based on an address indicated in the receiver address field 364 of the CTS-TRN frame 350. In response to the determining as being the intended receiving device for the CTS-TRN frame 350, the first device 410 may selectively use a beam training sequence in the beam training sequence field 368 of the received CTS-TRN frame 350 to configure an antenna of the first device 410 for directional transmission substantially targeting the second device 420. That is, the antenna of the first device 410 is configured to generate an antenna radiation pattern having a primary lobe (e.g., a highest gain lobe) substantially targeting the second device 420 and non-primary lobes targeting other directions.

The second device 420 is already aware of a direction toward the first device 410 on a basis of the beam training sequence of the beam training sequence field 320 in an RTS-TRN frame 300 previously received by the second device 420. Thus, the second device 420 may configure an antenna of the second device 420 selectively for directional reception targeting the first device 410 (e.g., a primary antenna radiation lobe). Therefore, while the antenna of the first device 410 is configured for the directional transmission to the second device 420 and the antenna of the second device 420 is configured for the directional reception from the first device 410, the first device 410 transmits one or more data frames to the second device 420. Accordingly, the first and second devices 410 and 420 perform directional transmission/reception DIR-TX/RX of one or more data frames through the primary lobe (the main beam).

Meanwhile, the first and second devices 410 and 420 may partially modify a beam pattern of the third device 430 to reduce interference with the third device 430 due to the antenna radiation pattern having the non-primary lobes.

In relation to this, the third device 430 determines that the third device 430 is not the intended receiving device for the CTS-TRN frame 350 on a basis of an address indicated in the receiver address field 364 of the CTS-TRN frame 350. In a response to the determining that the third device 430 is not the intended receiving device for the CTS-TRN frame 350, the third device 430 uses the beam training sequence in the beam training sequence field 368 of the received CTS-TRN 350 and a sequence of the beam training sequence field 320 in the RTS-TRN frame 300 previously received, to configure the antenna of the third device 430 to generate antenna radiation patterns having nulls substantially targeting the second device 420 and the first device 410, respectively. The nulls may be based on estimated angles of arrivals of the RTS-TRN frame 300 previously received, and the CTS-TRN frame 350. In general, the third device 430 generates antenna radiation patterns having desired signal powers, rejections or gains targeting the first device 410 and the second device 420, respectively (for example, to achieve an estimated interference in the first and second devices 410 and 420 to be equal to or less than a defined threshold value (e.g., to acquire desired BER, SNR, SINR and/or other one or more communication properties)).

The third device 430 may configure an antenna transmission radiation pattern of the third device 430 by estimating antenna gains in directions toward the first and second devices 410 and 420, estimating antenna reciprocity differences between the third device 430 and the first and second devices 410 and 420 (e.g., a transmission antenna gain minus a reception antenna gain), and respectively calculating the antenna gains and the antenna reciprocity differences throughout one or more sectors to determine estimated interferences corresponding to the first and second devices 410 and 420.

The third device 430 transmits the RTS-TRN frame 300 intended for the fourth device 440 and to be received by the fourth device 440. As long as the first and second devices 410 and 420 perform communication on a basis of durations indicated in duration fields of the duration fields 312 and 362 of the RTS-TRN frame 300 and the CTS-TRN frame 350, respectively, the third device 430 maintains an antenna configuration having nulls targeting such devices. Since the antenna of the third device 430 is configured to generate nulls targeting the first device 410 and the second device 420, transmission of the RTS-TRN frame 300 by the third device 430 may generate reduced interference in the first device 410 and the second device 420, respectively.

Accordingly, electronic devices supporting the 802.11ay wireless interface disclosed herein may configure a signal null direction in a particular direction to reduce interference while matching main beam directions with each other using an array antenna. To do so, a plurality of the electronic devices may configure an initial beam direction through a beam training sequence and change a beam direction through a periodically updated beam training sequence.

As described above, for high-speed data communication between the electronic devices, beam directions should be configured to match each other. In addition, a loss of a wireless signal transmitted to an antenna element needs to be minimized for high-speed data communication. To do so, an array antenna needs to be arranged in a multi-layer substrate on which a radio frequency integrated chip (RFIC) is arranged. In addition, for radiation efficiency, the array antenna needs to be arranged adjacent to a side region in the multi-layer substrate.

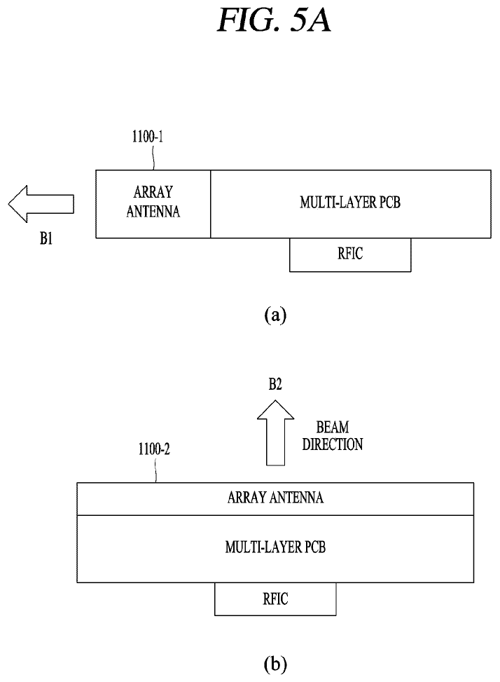

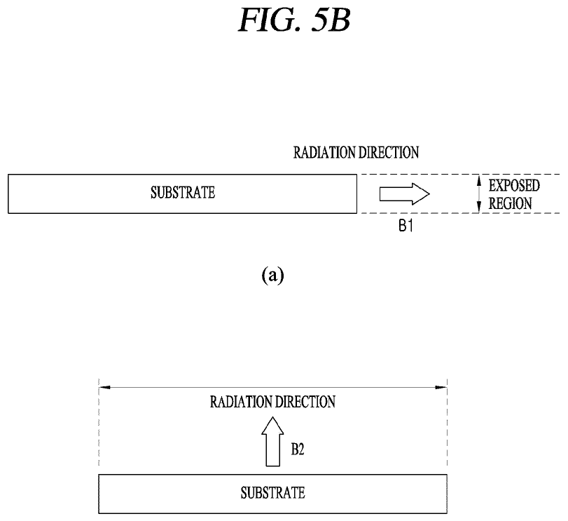

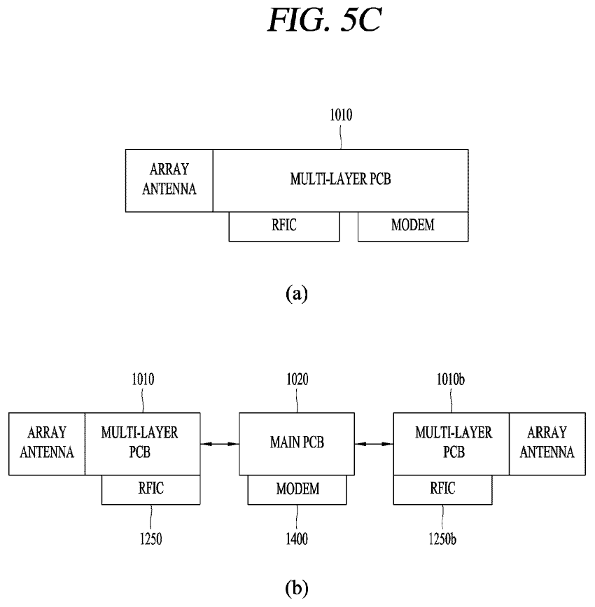

In addition, in order to adapt to a change in a wireless environment, a beam training sequence between the electronic devices needs to be updated. To update the beam training sequence, the RFIC needs to periodically transceive signals with a processor such as a modem. Therefore, to minimize update delay time, transception of a control signal between the RFIC and the modem needs to be performed within short time. To do so, a physical length of a connection path between the RFIC and the modem needs to be reduced. To do so, the modem may be arranged on a multi-layer substrate on which the array antenna and the RFIC are arranged. Alternatively, a connection length between the RFIC and the modem may be configured to be minimized in a structure in which the array antenna and the RFIC are arranged on the multi-layer substrate and the modem is arranged on a main substrate. In relation to this, a detailed structure will be described with reference to FIG. 5C.

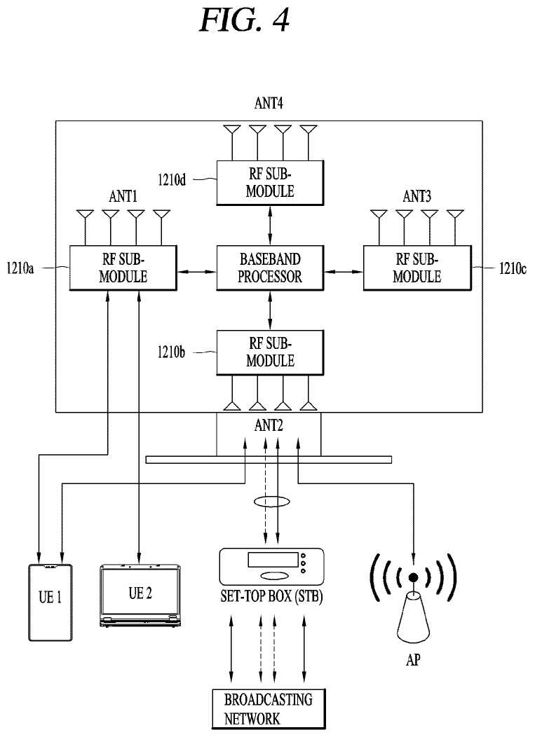

Hereinafter, an electronic device having an array antenna that may operate in a mm Wave band according to this specification will be described. In relation to this, FIG. 4 illustrates an electronic device in which a plurality of antenna modules and a plurality of transceiver circuit modules according to one embodiment are arranged. Referring to FIG. 4, a home appliance in which the plurality of antenna modules and the plurality of transceiver circuit modules are arranged may be a television, but is not limited thereto. Accordingly, in this specification, a home appliance in which the plurality of antenna modules and the plurality of transceiver circuit modules are arranged may include any home appliance or display device each configured to support a communication service in a mm Wave band.

Referring to FIG. 4, an electronic device 1000 includes a plurality of antenna modules ANT1 to ANT4 and a plurality of transceiver circuit modules 1210a to 1210d. In relation to this, the plurality of transceiver circuit modules 1210a to 1210d may correspond to a transceiver circuit 1250 as described above. Alternatively, the plurality of transceiver circuit modules 1210a to 1210d may be a partial configuration of the transceiver circuit 1250 or a partial configuration of a front end module arranged between the antenna module and the transceiver circuit 1250.

The plurality of antenna modules ANT 1 to ANT4 may be configured as an array antenna in which a plurality of antenna elements are arranged. A number of elements of the antenna modules ANT 1 to ANT4 is not limited to two, three, four, or the like as illustrated in the drawing. For example, the number of the elements of the antenna modules ANT 1 to ANT4 may extend to 2, 4, 8, 16, or the like. In addition, the elements of the antenna modules ANT 1 to ANT4 may be selected in a same number or in different numbers. The plurality of antenna modules ANT 1 to ANT4 may be arranged in different regions in a display, or in a lower portion or on a side surface of the electronic device. The plurality of antenna modules ANT 1 to ANT4 may be arranged in an upper portion, a left portion, a lower portion, or a right portion of the display. However, an arrangement structure thereof is not limited thereto. As another example, the antenna modules ANT 1 to ANT4 may be arranged in an upper left portion, an upper right portion, a lower left portion, or a lower right portion of the display.

The antenna modules ANT 1 to ANT4 may be configured to transmit or receive a signal in a particular direction in any frequency band. For example, the antenna modules ANT 1 to ANT4 may operate in any one of a 28 GHz band, a 39 GHz band, and a 64 GHz band.

The electronic device may maintain a connection state with different entities through two or more of the antenna modules ANT 1 to ANT4, or perform a data transmitting or receiving operation to maintain the connection state described above. In relation to this, the electronic device corresponding to a display device may transmit or receive data with a first entity through the first antenna module ANT1. Also, the electronic device may transmit or receive data with a second entity through the second antenna module ANT2. As an example, the electronic device may transmit or receive data to/from a mobile terminal UE through the first antenna module ANT1. The electronic device may transmit or receive data with a control device such as a set-top box or an access point (AP) through the second antenna module ANT2.

Data may be transmitted or received with another entity through other antenna modules, e.g., the third antenna module ANT3 and the fourth antenna module ANT4. As another example, dual connection or MIMO may be performed through at least one of the first and second entities both previously connected via the third antenna module ANT3 and the fourth antenna module ANT4.

Mobile terminals UE1 and UE2 may be arranged in a front of the electronic device, and configured to communicate with the first antenna module ANT1. Meanwhile, the set-top box (STB) or the access point AP may be arranged in a lower portion of the electronic device, and configured to communicate with the second antenna module ANT2, but is not limited thereto. As another example, the second antenna module ANT2 may include both a first antenna radiating toward a lower region and a second antenna radiating toward a front region. Accordingly, the second antenna module ANT2 may communicate with the set-top box (STB) or the access point AP through the first antenna, and with one of the mobile terminals UE1 and UE2 through the second antenna.

Meanwhile, one of the mobile terminals UE1 and UE2 may be configured to perform MIMO with the electronic device. As an example, the UE1 may be configured to perform MIMO while performing beamforming with the electronic device. As described above, the electronic device corresponding to the image display device may perform high-speed communication with another electronic device or the set-top box STB through a WiFi wireless interface. As an example, the electronic device may perform high-speed communication in a 60 GHz band with another electronic device or the set-top box STB through the 802.11ay wireless interface.

Meanwhile, the transceiver circuit modules 1210a to 1210d may operate to process a transmission signal and a reception signal in an RF frequency band. Here, the RF frequency band may be any frequency band of a millimeter band, such as a 28 GHz band, a 39 GHz band, and a 64 GHz band, as described above. The transceiver circuit modules 1210a to 1210d may be referred to as RF sub-modules 1210a to 1210d. In this case, the number of the RF sub-modules 1210a to 1210d is not limited to four, and may be changed to an arbitrary number of two or more depending on applications.

In addition, the RF sub-modules 1210a to 1210d may include an up-conversion module and a down-conversion module that convert a signal in the RF frequency band into a signal in an IF (intermediate frequency) band or convert a signal in the IF frequency band into a signal in the RF frequency band. To do so, the up-conversion module and the down-conversion module may respectively include a local oscillator (LO) capable of performing up-frequency conversion and down-frequency conversion.

Meanwhile, the plurality of RF sub-modules 1210a to 1210d may be configured such that a signal is transmitted from one module among the plurality of transceiver circuit modules to an adjacent transceiver circuit module. Accordingly, the transmitted signal may be configured to transmitted to all of the plurality of transceiver circuit modules 1210a to 1210d at least once.

To do so, a data transmission path (data transfer path) having a loop structure may be added. In relation to this, the RF sub-modules 1210b and 1210c may bidirectionally transmit a signal to an adjacent RF sub-module through a transfer path P2 having the loop structure.

Alternatively, a data transmission path having a feedback structure may be added. In relation to this, through the data transmission path having the feedback structure, at least one sub-module 1210c may transmit a signal to the other sub-modules 1210a, 1210b, and 1210c unidirectionally.

The plurality of RF sub-modules may include first to fourth RF sub-modules 1210a to 1210d. In relation to this, a signal from the first RF sub-module 1210a may be transmitted to the RF sub-module 1210b and the fourth RF sub-module 1210d both adjacent thereto. In addition, the second RF sub-module 1210b and the fourth RF sub-module 1210d may transmit the signal to the third RF sub-module 1210c adjacent thereto. At this time, when bidirectional transmission between the second RF sub-module 1210b and the third RF sub-module 1210c may be performed as shown in FIG. 4, this may be referred to as a loop structure. On the other hand, when only unidirectional transmission may be performed between the second RF sub-module 1210b and the third RF sub-module 1210c, this may be referred to as a feedback structure. Meanwhile, in the feedback structure, at least two signals may be transmitted to the third RF sub-module 1210c.

However, a structure is not limited thereto, and a baseband module may be included only in a particular module among the first to fourth RF sub-modules 1210a to 1210d depending on applications. Alternatively, depending on an application, a baseband module may not be included in the first to fourth RF sub-modules 1210a to 1210d, but may be configured as a separate controller, that is, a baseband processor 1400. For example, a control signal may be transmitted only by a separate controller, that is, the baseband processor 1400.

Meanwhile, a specific configuration and function of the electronic device illustrated in FIG. 1 and including the wireless interface of FIG. 2 will be described. Transmission or reception of data between electronic devices needs to be performed using a communication service between the electronic devices in a mm Wave band. In relation to this, a wireless audio-video (AV) service and/or high-speed data transmission may be provided using the 802.11ay wireless interface as a mm Wave wireless interface. In this case, the mm Wave wireless interface is not limited to the 802.11ay wireless interface, and any wireless interface of a 60 GHz band may be adopted. In relation to this, a 5G or 6G wireless interface using a 28 GHz band or a 60 GHz band may be used for high-speed data transmission between electronic devices.

There is a problem such that, with respect to an antenna and an RFIC configured to provide a wireless interface in an electronic device such as an image display device, a specific solution for transmitting an image with a resolution of 4 K or higher is not present. In particular, in consideration of a situation in which an electronic device such as an image display device is arranged on a wall of a building or on a table, wireless AV data may need to be transmitted or received to/from another electronic device. To do so, with respect to regions in which the antenna and the RFIC are to be arranged in the image display device, a specific configuration and an antenna structure need to be presented.

In this regard, FIG. 5A illustrates a configuration in which a multi-layer circuit substrate on which an array antenna module is arranged is connected to an RFIC, in relation to this specification. Specifically, in relation to this specification, a structure of an antenna in package (AIP) module and an antenna module structure implemented on a flexible substrate are illustrated.

Referring to (a) of FIG. 5A, the AIP module is configured as an RFIC-PCB-antenna integrated type for mm Wave band communication. In relation to this, an array antenna module 1100-1 may be configured integrally with a multi-layer substrate (a multi-layer printed circuit board (PCB)) as illustrated in (a) of FIG. 5A. Accordingly, the array antenna module 1100-1 configured integrally with the multi-layer substrate may be referred to as an AIP module. Specifically, the array antenna module 1100-1 may be arranged in one side region of the multi-layer substrate. In relation to this, a first beam B1 may be generated in a side region of the multi-layer substrate using the array antenna module 1100-1 arranged on the one side region of the multi-layer substrate.

On the other hand, referring to (b) of FIG. 5A, an array antenna module 1100-2 may be arranged on the multi-layer substrate. The arrangement of the array antenna module 1100-2 is not limited to the structure of (b) of FIG. 5A, but may be performed on any layer inside the multi-layer substrate. In relation to this, a second beam B2 may be generated toward a front region of the multi-layer substrate using the array antenna module 1100-2 arranged on any layer of the multi-layer substrate. In relation to this, in a case of the AIP module in which an array antenna module is integrally arranged, an array antenna may be arranged on a same PCB to minimize a distance between the RFIC and the antenna.

Meanwhile, the antenna of the AIP module may be implemented using a multi-layer PCB manufacturing process, and radiate a signal in a vertical/side direction of the PCB. In relation to this, double polarization may be implemented using a patch antenna or a dipole/monopole antenna. Accordingly, the first array antenna 1100-1 shown in (a) of FIG. 5A may be arranged on a side region of the multi-layer substrate, and the second array antenna 1100-2 shown in (b) of FIG. 5A may be arranged on a side region of the multi-layer substrate. Therefore, the first beam B1 may be generated through the first array antenna 1100-1, and the second beam B2 may be generated through the second array antenna 1100-2.

The first array antenna 1100-1 and the second array antenna 1100-2 may be configured to have same polarization. Alternatively, the first array antenna 1100-1 and the second array antenna 1100-2 may be configured to have orthogonal polarization. In this regard, the first array antenna 1100-1 may operate as a vertically polarized antenna or operate as a horizontally polarized antenna. As an example, the first array antenna 1100-1 may be a monopole antenna having vertical polarization, and the second array antenna may be a patch antenna having horizontal polarization.

Meanwhile, FIG. 5B is a conceptual diagram illustrating antenna structures having different radiation directions.

Referring to (a) of FIG. 5A and (a) of FIG. 5B, a radiation direction of an antenna module arranged in the side region of the multi-layer substrate corresponds to a side direction. In relation to this, antennas implemented on a flexible substrate may be configured as radiating elements such as a dipole/monopole antenna. That is, antennas implemented on the flexible substrate may be end-fire antenna elements.

In relation to this. end-fire radiation may be implemented by an antenna radiating in a direction horizontal to the substrate. Such an end-fire antenna may be implemented as a dipole/monopole antenna, a Yagi-dipole antenna, a Vivaldi antenna, a substrate integrated waveguide (SIW) horn antenna, or the like. In relation to this, the Yagi-dipole antenna and the Vivaldi antenna have horizontal polarization characteristics. Meanwhile, one of antenna modules arranged in the image display device disclosed herein needs a vertically polarized antenna. Accordingly, there is a need to present an antenna structure capable of minimizing an antenna exposure region while operating as a vertically polarized antenna.

Referring to (b) of FIG. 5A and (a) of FIG. 5B, a radiation direction of the antenna module arranged on a front region of the multi-layer substrate corresponds to a front direction. In relation to this, an antenna arranged in the AIP module may be configured as a radiating element such as a patch antenna. That is, antennas arranged in the AIP module may be broadside antenna elements radiating in a broadside direction.

Meanwhile, the multi-layer substrate having the array antenna placed therein may be arranged integrally with a main substrate or may be configured to be combined with the main substrate as a modular type by a connector. In relation to this, FIG. 5C illustrates a combination structure between the multi-layer substrate and the main substrate according to embodiments. Referring to (a) of FIG. 5C, a structure in which an RFIC 1250 and a modem 1400 are integrally arranged on a multi-layer substrate 1010 is shown. The modem 1400 may be referred to as the baseband processor 1400. Accordingly, the multi-layer substrate 1010 is arranged integrally with the main substrate. Such an integrated structure may be applied to a structure in which only one array antenna module is arranged in the electronic device.

On the other hand, the multi-layer substrate 1010 and a main substrate 10120 may be configured to be combined with each other as a modular type by a connector. Referring to (b) of FIG. 5C, in relation to this, the multi-layer substrate 1010 may be configured to interface with the main substrate 1020 through a connector. In this case, the RFIC 1250 may be arranged on the multi-layer substrate 1010, and the modem 1400 may be arranged on the main substrate 1020. Accordingly, the multi-layer substrate 1010 may be configured as a substrate separate from the main substrate 1020 and configured to be combined with the main substrate 1020 through the connector.

Such a modular structure may be applied to a structure in which a plurality of array antenna modules are arranged in the electronic device. Referring to (b) of FIG. 5C, the multi-layer substrate 1010 and a second multi-layer substrate 1020 may be configured to interface with the main substrate 1020 through connector connection. The modem 1400 arranged on the main substrate 1020 is configured to be electrically coupled to RFICs 1250 and 1250b arranged on the multi-layer PCB 1010 and a second multi-layer PCB 1020, respectively.

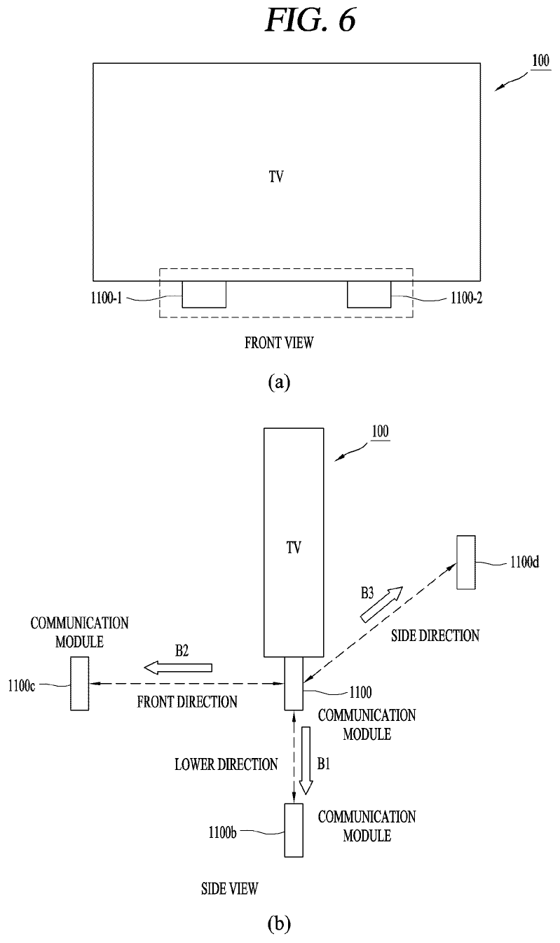

Meanwhile, when the AIP module is arranged in a lower portion of the electronic device such as an image display device, communication needs to be performed with other communication modules arranged in a lower direction and a front direction. In relation to this, FIG. 6 is a conceptual diagram illustrating a plurality of communication modules arranged in a lower portion of an image display device, a configuration of the corresponding communication modules, and communication performed between the communication modules and other communication modules arranged in a front direction. Referring to (a) of FIG. 6, different communication modules 1100-1 and 1100-2 may be arranged in a lower portion of the image display device 100. Referring to (b) of FIG. 6, the image display device 100 may perform communication with a communication module 1100b arranged therebelow through an antenna module 1100. In addition, communication may be performed with a second communication module 1100c arranged in front of the image display device 100 through the antenna module 1100 of the image display device 100. In relation to this, the communication module 1100b may be a set-top box or an access point (AP) that transmits AV data to the image display device 100 through an 802.11ay wireless interface at a high speed, but is limited thereto. Meanwhile, the second communication module 1100c may be any electronic device that transceives data to/from the image display device 100 at a high speed through the 802.11ay wireless interface.

Meanwhile, in the AIP module structure as illustrated in (a) of FIG. 5A, an antenna height may increase depending on an RFIC driving circuit and a heat dissipation structure. Also, depending on a type of an antenna that is being used, an antenna height may increase in the AIP module structure as shown in (a) of FIG. 5A. On the other hand, in the antenna module structure implemented in a side region of the multi-layer substrate as illustrated in (b) of FIG. 5A, an antenna may be implemented in a low-profile shape.

Meanwhile, a detailed configuration of the antenna modules of FIGS. 5A to 5C, which may be arranged inside or on a side surface of the electronic device of FIGS. 4 and 6, in the electronic device of FIGS. 1 to 2 and the configurations of FIGS. 3A and 3B, is to be described.

A communication module including an antenna may be arranged so that an electronic device such as an image display device may perform communication with a neighboring electronic device. Meanwhile, recently, as a display area of an image display device is enlarged, an arrangement space of a communication module including an antenna is reduced. Accordingly, there is an increasing need to arrange an antenna in a multi-layer circuit substrate on which a communication module is implemented.

Meanwhile, a WiFi wireless interface may be taken into account, as an interface for a communication service between electronic devices. When such a WiFi wireless interface is used, a millimeter wave (mmWave) band may be used for high-speed data transmission between electronic devices. In particular, high-speed data transmission between the electronic devices may be performed using a wireless interface such as an 802.11ay wireless interface.

In relation to this, an array antenna capable of operating in a mmWave band may be mounted in an antenna module. However, electronic components such as an antenna and a transceiver circuit arranged in such an antenna module are configured to be electrically connected to each other. To do so, the transceiver circuit may be operably coupled to the antenna module, and the antenna module may be configured as a multi-layer substrate.

As the multi-layer substrate of the antenna module is arranged to have a planar stacked structure, a constraint may occur when a vertically polarized antenna is implemented. In this regard, a length of the vertically polarized antenna may be configured to be greater than a height of the multi-layer substrate. Due to the constraint in the height of the multi-layer substrate, there is a problem in that antenna performance may deteriorate when the vertically polarized antenna is configured to have a small length.

In addition, when a dual-polarized antenna for a horizontally polarized antenna and a vertically polarized antenna is implemented, a combination structure between PCBs of different multi-layer substrates may be configured. In the combination structure between the PCBs of these different multi-layer substrates, lengths from respective feed lines to the vertically polarized antenna and the horizontally polarized antenna may be configured to be different from each other. Accordingly, performance differences between the vertically polarized antenna and the horizontally polarized antenna may occur, or a feed loss may increase in a mm Wave band due to an increase in lengths of the feed lines. Therefore, there is a problem such that an antenna gain of an antenna module having the combination structure between PCBs of different multi-layer substrates may be worsened.

An object of this specification to solve the above-mentioned problems is to provide an antenna module in which a dual-polarized antenna operating in a mmWave band is implemented, and an electronic device including the antenna module. Another object of this specification is to implement an antenna performing radiation from one side of a PCB using an FPCB. Another object of this specification is to provide a dual-polarized end-fire antenna such that a dual-polarized antenna operating as a horizontally polarized antenna and a vertically polarized antenna performs radiation through one side of a PCB. Another object of this specification is to provide a vertically polarized antenna through an asymmetric dipole antenna arranged on an FPCB and a PCB. Another object of this specification is to arrange an FPCB to be vertical to a PCB to implement vertical polarization even at a height of the PCB which is insufficient to implement the vertical polarization. Another object of this specification is to implement one pole on an FPCB and another pole on a PCB as radiators to improve performance of vertical polarization, thereby increasing an area to enhance radiation performance. Another object of this specification is to minimize an area occupied by antennas in a limited substrate region by arranging a vertically polarized antenna and a horizontally polarized antenna in an overlapping region. Another object of this specification is to perform wireless communication with a peripheral electronic device by optimally arranging an antenna module on a lower portion of an electronic device.

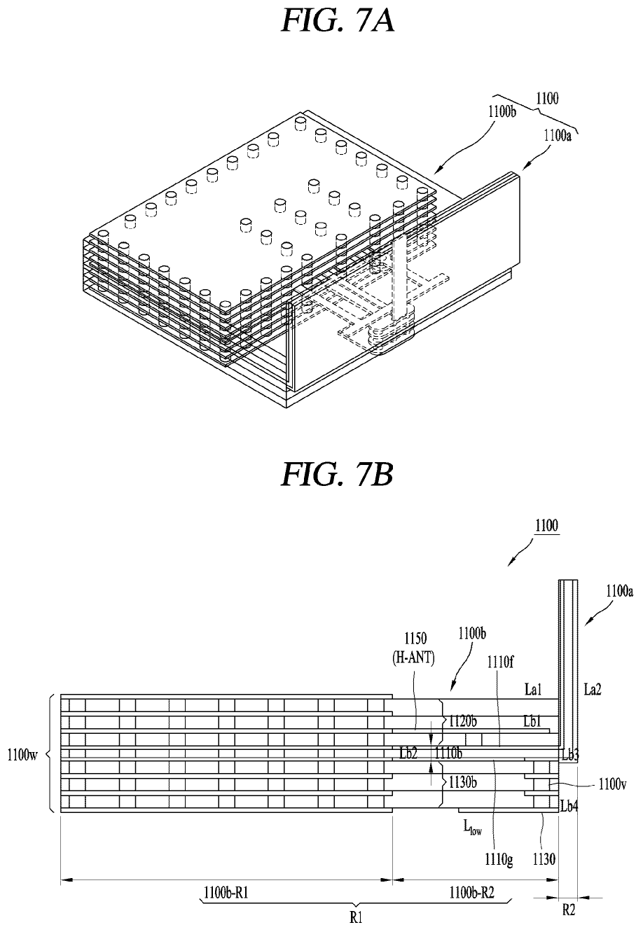

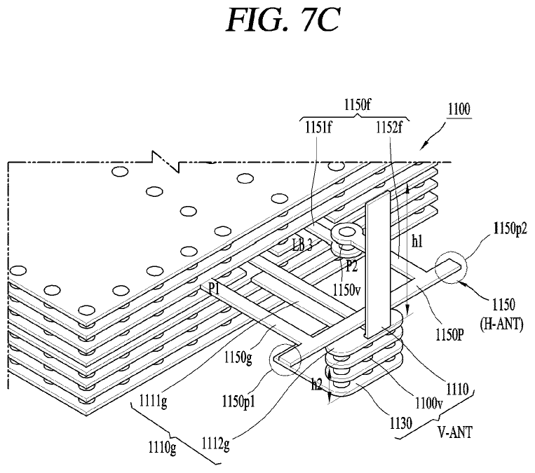

Hereinafter, an antenna module that operates in a mmWave band according to this specification, and an electronic device including the antenna module are to be described. In this regard, FIG. 7A is a perspective view of a structure in which a PCB and an FPCB each having antenna elements arranged thereon are connected to each other. FIG. 7B is a side view of the structure in which the PCB and FPCB of FIG. 7A are connected to each other. FIG. 7C illustrates a structure of a dual-polarized antenna excluding a dielectric region of the PCB.

Referring to FIGS. 7A and 7B, the antenna module 1100 may be configured to include a flexible printed circuit board (FPCB) 1100a and a printed circuit board (PCB) 1100b which is a multi-layer substrate. The FPCB 1100a may include a first conductive pattern 1110 arranged on a first layer La1, and a second layer La2.

The antenna module 1000 may be constituted by the multi-layer substrates (multi-layered substrates) 1100a and 1100b made of a plurality of dielectric materials, and conductive patterns. The FPCB 1100a and the PCB 1100b may be implemented as the multi-layer substrates (multi-layered substrates). The multi-layer substrates 1100a and 1100b may be configured to include a first layer 1110b, second layers 1120b, and third layers 1130b.

The first layer 1110b may be made of a flexible first material. The second layers 1120b may include a plurality of layers made of a rigid second material arranged on one side surface of the first layer 1110b. The third layers 1130b may include a plurality of layers made of the rigid second material arranged on another side surface of the first layer 1110b. The first layer 1110b may be placed between the second layers 1120b and the third layers 1130b of the multi-layer substrates 1100a and 1100b.

The first layer 1110b may include a first region R1 arranged in parallel with the second layers 1120b and the third layers 1130b, and a second region R2 arranged vertically to the second layers 1120b and the third layers 1130b. The first region R1 may be a PCB region and the second region R2 may be an FPCB region. The first region R1 may be configured to include a ground region 1100b-R1 in which a ground wall 1100w is placed and a dielectric region 1100b-R2 in which conductive patterns constituting antennas are placed.

Referring to FIG. 7C, the conductive patterns may constitute a vertically polarized antenna V-ANT and a horizontally polarized antenna H-ANT. The first conductive pattern 1110 may be implemented as the vertically polarized antenna. A second conductive pattern 1151f and a third conductive pattern 1150 may be implemented as the horizontally polarized antenna. The second conductive pattern 1151f and the third conductive pattern 1150 may be connected to each other by a first via hole 1150v. As another example, the third conductive pattern 1150 may be configured to include a first sub-pattern 1152f, a second sub-pattern 1150, and a third sub-pattern 1150g. The second conductive pattern 1151f and the first sub-pattern 1152f of the third conductive pattern 1150 may constitute a feed line 1150f (or a feed pattern).

The vertically polarized antenna may include the first conductive pattern 1110, a fourth conductive pattern 1110g, and a fifth conductive pattern 1130. The fourth conductive pattern 1110g may be configured to include a fourth sub-pattern 1111g and a fifth sub-pattern 1112g. The fourth conductive pattern 1110g and the fifth conductive pattern 1130 may be connected to each other by a second via hole 1100v.

The antenna module 1100 may operate as a dual-polarized antenna including the horizontally polarized antenna H-ANT and the vertically polarized antenna V-ANT. The horizontally polarized antenna H-ANT may be implemented as a loop antenna 1150. The vertically polarized antenna V-ANT may be configured to include the first conductive pattern 1110, the second via hole 1100v, and the fifth conductive pattern 1130.

The third conductive pattern 1150 arranged on a second sub-layer Lb2, which is another layer among the second layers 1120b, may be constituted by the first sub-pattern 1152f, a second sub-pattern 1150p, and the third sub-pattern 1150g. The first sub-pattern 1152f may be connected to the second conductive pattern 1151f by the first via hole 1150v. One region of the third sub-pattern 1150g may be connected to ground of the multi-layer substrate. The first sub-pattern 1152f and the third sub-pattern 1150g may be connected to each other by the second sub-pattern 1150p.

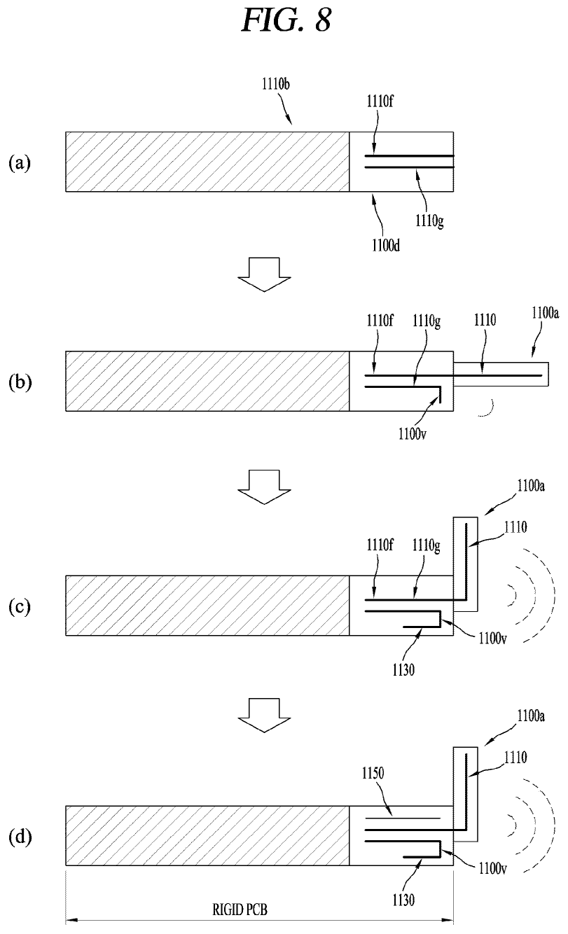

FIG. 8 illustrates various configurations in which a PCB having a feed pattern and a ground pattern placed thereon and an FPCB are connected to each other. Referring to FIG. 8, a structure and a radiation principle of a dual-polarized end-fire antenna in this specification are described.

Referring to (a) of FIG. 8, a first structure in which a feed line 1110f and a ground line 1110g are arranged in a dielectric region 1100d of the PCB 1100b is shown. The feed line 1110f of the vertically polarized antenna is configured to connect the antenna to an RFIC on the PCB 1100b which is rigid. The first structure lacks a sufficient space in which a radiator having a pole structure is to be vertically arranged in the PCB without an FPCB. Thus, an amount of radiation according to an electric field of the feed line 1110f is at a critical level or lower, which is very small.

Referring to (b) of FIG. 8, a second structure may be configured to connect the FPCB 1100a to the PCB 1100b to thereby secure a space in which a radiator having a pole structure is to be vertically arranged inside the PCB. The first conductive pattern 1100 which is a radiator having a pole structure may be arranged on the FPCB 1100a of the second structure. As the first conductive pattern 1100 is arranged on a horizontal surface, a radiation region may be generated in a lower region of the FPCB 1100a. A via structure 1100v may be arranged at an end portion of the ground line 1110g of the dielectric region 1100d of the second structure. A second conductive pattern may be arranged in parallel with the first conductive pattern on the FPCB 1100a of the second structure. The second conductive pattern may operate as ground of the first conductive pattern 1110 or be connected to the first conductive pattern 1110 through a via to operate as a radiator.

Referring to (c) of FIG. 8, a third structure may be arranged to have a shape in which the FPCB 1100a is bent substantially vertically to the PCB 1100b at an angle of about 90 degrees. In the third structure, a first conductive pattern 1100a arranged on the FPCB 1100a may define an upper-end pole as a first portion of the vertically polarized antenna. In the third structure, the via structure 1100v and the fifth conductive pattern 1130 arranged on the PCB 1100b may constitute a lower-end pole as a second portion of the vertically polarized antenna. The lower-end pole may extend an antenna length vertically through the via structure 1100v inside the PCB 1100b.

By folding the FPCB 1100a upward to arrange the first conductive pattern 1110 vertically and extending the lower-end pole into a C shape through the fifth conductive pattern 1130, a sufficient antenna length may be obtained using the upper-end pole and the lower-end pole to thereby increase an amount of radiation.

Referring to (d) of FIG. 8, a region in which a conductor is empty for radiation of the vertically polarized antenna is generated in the rigid PCB 1100b. A dual-polarized end-fire antenna may be implemented by implementing the horizontally polarized antenna 1150 in the region in which a conductor is empty.

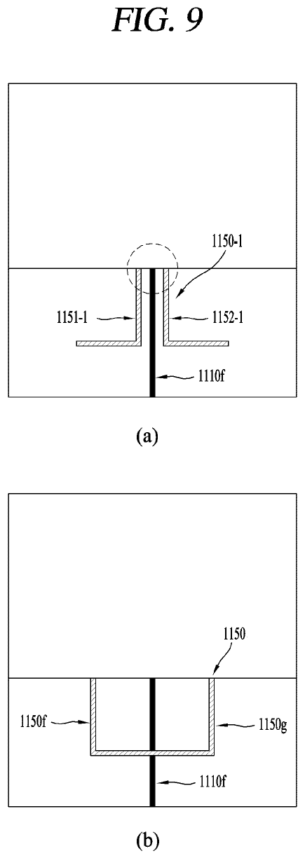

Meanwhile, antenna elements constituting a dual-polarized antenna of the antenna module according to this specification may be arranged in corresponding regions on different layers. In this regard, FIG. 9 illustrates structures of a vertically polarized antenna and a horizontally polarized antenna according to embodiments.

Referring to (a) of FIG. 9, a structure in which a first conductive line 1151-1 and a second conductive line 1152-1 of a horizontally polarized antenna 1150-1 are arranged, within a critical distance, on one side and another side of the feed line 1110f of a vertically polarized antenna is shown. The horizontally polarized antenna 1150-1 may be implemented as a dipole antenna. The conductive lines 1151-1 and 1152-1 of the horizontally polarized antenna 1150-1 may be placed adjacent to the feed line 1110f of the vertically polarized antenna. Thus, a level of interference between antennas may be increased.

Referring to (b) of FIG. 9, a structure in which the feed line 1150f and a third conductive line 1150g of the horizontally polarized antenna 1150 are arranged to be spaced apart from each other on one side and another side of the feed line 1110f of the vertically polarized antenna is shown. The horizontally polarized antenna 1150 may be implemented as a loop antenna. The feed line 1150f of the horizontally polarized antenna 1150 may be spaced apart from the feed line 1110f of the vertically polarized antenna by a critical distance or more to thereby reduce a level of interference between the antennas.

Referring to (b) of FIG. 9, when the horizontally polarized antenna 1150 and the vertically polarized antenna are implemented to overlap each other, a loop antenna grounded with a ground may be used as the horizontally polarized antenna 1150.

As shown in (a) of FIG. 9, two issues may arise when a dipole antenna which is not grounded with a ground is used. (1) A horizontal polarization antenna and a vertically polarized antenna cannot be implemented to overlap each other in a same region. In this regard, the feed line 1110f and the conductive lines 1151-1 and 1152-1 may overlap each other or be positioned very closely, thus resulting in significant mutual coupling. (2) When separate antenna regions are used for a horizontally polarized antenna and a vertically polarized antenna, a whole antenna size is increased. Accordingly, antenna miniaturization may not be performed, and when array antennas are implemented, distortion of a radiation pattern occurs due to mutual influence between the antennas. Therefore, a loop type antenna having a structure separate from the feed line 1110f as shown in (b) of FIG. 9 needs to be used.

Referring to FIGS. 7A to 9, the antenna module 1000 implemented as a dual-polarized antenna according to this specification may be configured to include the flexible printed circuit board (FPCB) 1100a and the printed circuit board (PCB) 1100b which is a multi-layer substrate. The FPCB 1100a may include a plurality of layers. The FPCB 1100a may include the first conductive pattern 1110 arranged on a first layer. The PCB 1100b may be configured to include the first layer 1110b, the second layers 1120b, and the third layers 1130b.

The first conductive pattern 1110 may be arranged on the first layer La1 on one side of layers made of a flexible material. The first conductive pattern 1110 may be configured to have a shape substantially vertically bent at an angle of 90 degrees to be connected to a first sub-layer Lb1 of the PCB 1100b.

The second layer La2 may be placed on another side of the layers of the FPCB 1100a. A second conductive pattern may be placed on the second layer La2, but the second layer La2 is not limited thereto. The second layer La2 may correspond to the second sub-layer Lb2 of the PCB 1100b. In a structure in which the second conductive pattern is arranged on the second layer La2, the second conductive pattern may be connected to the second sub-layer Lb2 of the PCB 1100b.

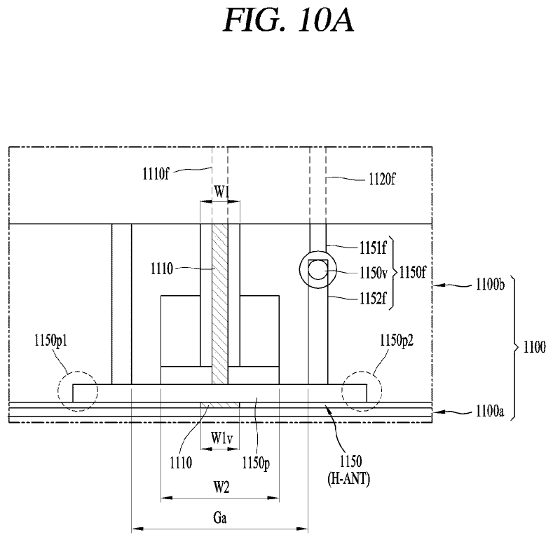

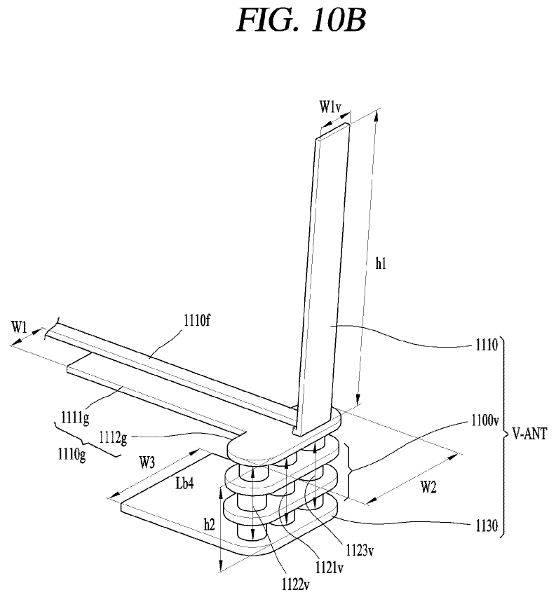

Meanwhile, in an antenna module having a dual-polarized antenna according to this specification, a horizontally polarized antenna and a vertically polarized antenna may be arranged to overlap each other in corresponding regions of different layers. In this regard, FIG. 10A is a front view of a structure in which a vertically polarized antenna and a vertically polarized antenna are arranged in corresponding regions of different layers in the dual-polarized antenna structure of FIGS. 7A to 7C. FIG. 10B illustrates a vertically polarized antenna structure constituted by an upper-end pole and a lower-end pole in the dual-polarized antenna structure of FIGS. 7A to 7C.

Referring to FIGS. 7A to 10A, in the rigid PCB 1100b, the horizontally polarized H-ANT may be configured to include the second conductive 1151f and the third conductive pattern 1150. As another example, the third conductive pattern 1150 may be configured to include the first sub-pattern 1152f, a second sub-pattern 1150p, and the third sub-pattern 1150g.

A length of the second sub-pattern 1150p may be configured to be greater than a space Ga in a gap between the first sub-pattern 1152f and the third sub-pattern 1150g. Accordingly, a horizontally polarized antenna implemented in a loop shape may be implemented as a pi (p)-shaped loop antenna. The second sub-pattern 1150p may be constituted by pattern regions 1150p1 and 1150p2 extending, toward both sides, from two portions connected to a pattern region between the first sub-pattern 1152f and the third sub-pattern 1150g. The first conductive pattern 1110 placed in the first region R1 of the multi-layer substrate may be arranged in a middle region between the first sub-pattern 1152f and the third sub-pattern 1150g.

In the embodiment of this specification, a pi loop antenna having a pi (ð) shape is used. However, the loop antenna is not limited thereto, and may be modified depending on application. A feed line of the horizontally polarized antenna H-ANT implemented as the pi loop antenna may be placed on a same layer as that of a feed line of a vertically polarized antenna. Accordingly, one of conductive patterns of the horizontally polarized antenna and the feed line 1110f of the vertically polarized antenna may overlap each other to be shorted. To solve this issue, the second conductive pattern 1151f may be vertically connected to a first sub-pattern 1152 of the third conductive pattern 1150 through the first via hole 1150v. Accordingly, the feed line of the horizontally polarized antenna H-ANT may be placed on a different layer from that of the feed line of the vertically polarized antenna. Therefore, the feed line 1150f in a loop antenna structure of the horizontally polarized antenna H-ANT may be implemented as sub-patterns on different layers.

Referring to FIGS. 7A to 10B, the vertically polarized antenna V-ANT may be configured to include the first conductive pattern 1110, the fourth conductive pattern 1110g, and the fifth conductive pattern 1150. The fourth conductive pattern 1110g may be configured to include the fourth sub-pattern 1111g and the fifth sub-pattern 1112g. The fourth conductive pattern 1110g and the fifth conductive pattern 1150 of the vertical polarized antenna V-ANT may be configured as a C-shaped or inverted C-shaped pole. In this regard, a C-shaped or inverted C-shaped pole including the via hole 1100v and a via pad may be configured.

The inverted C-shaped pole may be referred to as a lower-end pole. Since a width of the lower-end pole of the vertically polarized antenna V-ANT, and the fourth conductive pattern 1110g and the feed line 1110f of the horizontally polarized antenna H-ANT mutually affect each other, an implementation condition needs to be established. A width W2 of the third conductive pattern, which is the lower-end pole of the vertically polarized antenna V-ANT, may be configured to be equal to or different from a width W2 of the fifth sub-pattern 1112gwithin a predetermined range. This may be configured to be smaller than a space Ga between the third sub-pattern 1150g and the feed line 1150f of the horizontally polarized antenna H-ANT.

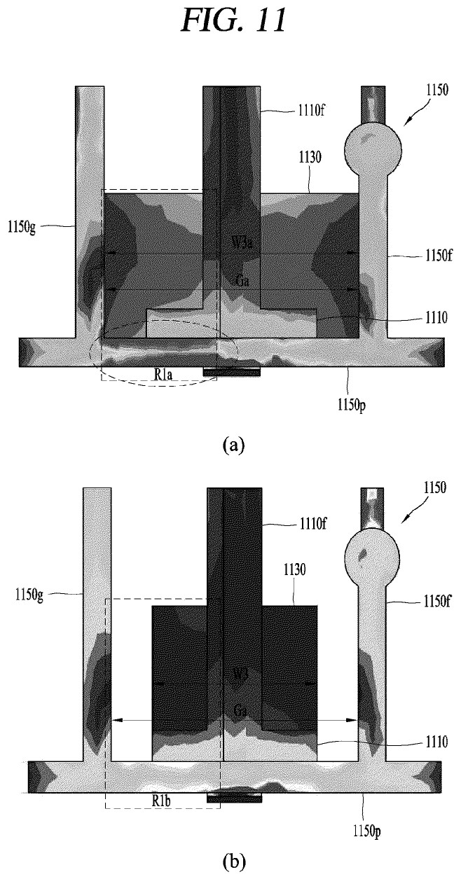

As described above, a shape and a size of a conductive pattern in the dual-polarized antenna according to this specification may be optimized to minimize a level of mutual interference. In this regard, FIG. 11 shows a comparison between current distribution diagrams in correspondence with coupling between antennas according to a change in a width of a third conductive pattern of a vertically polarized antenna. Referring to FIG. 11, current distributions due to coupling which occurs when a signal is applied to a horizontally polarized antenna are shown.

(a) of FIG. 11 illustrates a first structure in which a width W3a of the fifth conductive pattern 1130 is configured to be identical to the space Ga between the third sub-pattern 1150g and the feed line 1150f of the horizontally polarized antenna H-ANT. (b) of FIG. 11 illustrates a second structure in which a width W3 of the fifth conductive pattern 1130 is configured to be smaller than the space Ga between the third sub-pattern 1150g and the feed line 1150f of the horizontally polarized antenna H-ANT.

Referring to (a) of FIG. 11, the width W3a of the fifth conductive pattern 1130, which is a lower-end pole of a vertically polarized antenna, may be equal to or greater than the space Ga between the first sub-pattern 1110g and the third sub-pattern 1150g of the horizontally polarized antenna. Accordingly, interference between antennas increases significantly, thereby deteriorating radiation performance. When a signal is applied to the horizontally polarized antenna, a high current distribution is generated in one side region R1a of the second sub-pattern 1150p. Referring to (b) of FIG. 11, the width W3 of the fifth conductive pattern 1130 which is a lower-end pole may be configured to be smaller than the space Ga between the third sub-pattern 1150g and the feed line 1110g. Accordingly, it may be checked that coupling is significantly reduced in one side region R1b of the second sub-pattern 1150p when a signal is applied to the horizontally polarized antenna.

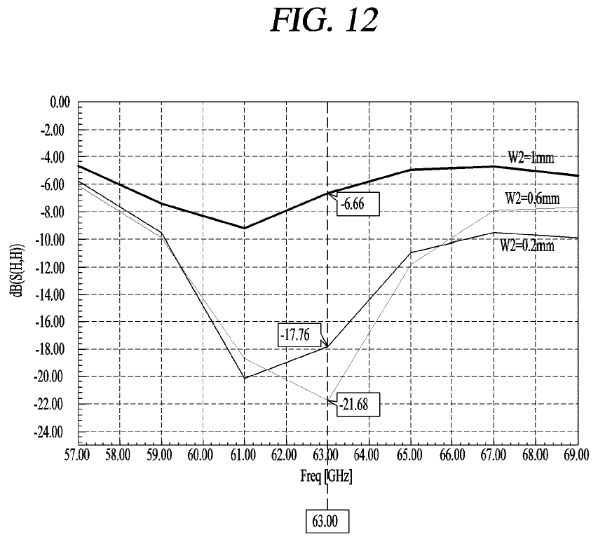

Meanwhile, in an antenna module implemented as a dual-polarized antenna according to this specification, performance of a horizontally polarized antenna may vary depending on the width W3 of the fifth conductive pattern 1130 which is a lower-end pole. In this regard, FIG. 12 shows reflection coefficient characteristics of a horizontally polarized antenna according to a width of a third conductive pattern, which is a lower-end pole, in an antenna module implemented as a dual-polarized antenna.

Referring to FIGS. 10A to 12, the space Ga between the third sub-pattern 1150g and the feed line 1110g may be configured to be 0.9 mm. As the width W3 of the fifth conductive pattern 1130 which is a lower-end pole is changed to 0.2 mm, 0.6 mm, or 1 mm, a reflection coefficient characteristic S11 is changed. When the width W3 of the fifth conductive pattern 1130 which is a lower-end pole is configured to be 1 mm, which is a value greater than that of the space Ga between the third sub-pattern 1150g and the feed line 1110g, S11 is −6.7 dB at 63 GHz. The width W3 of the fifth conductive pattern 1130 which is a lower-end pole may be configured to be 0.2 mm or 0.6 mm, which is smaller than a space Ga of 0.9 mm. When the width W3 of the fifth conductive pattern 1130 is configured to be 0.2 mm and 0.6 mm, S11 is −17.7 dB and −21.7 dB at 63 GHz, which shows performance improved by 11 dB and 15 dB, respectively.

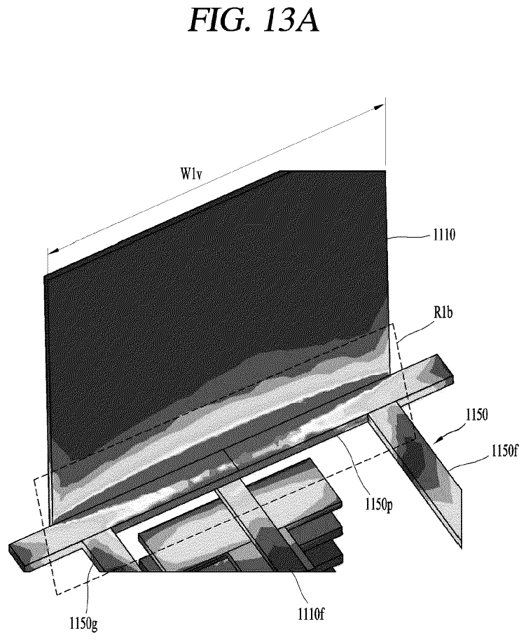

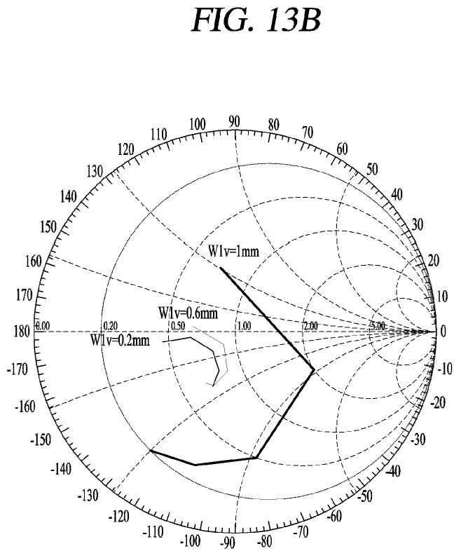

Meanwhile, in an antenna module implemented as a dual-polarized antenna according to this specification, as a width W1v of the first conductive pattern 1110 which is an upper-end pole of a vertically polarized antenna is changed, performance of a vertically polarized antenna may be changed. In this regard, FIG. 13A shows a current distribution diagram in a case when a width of a first conductive pattern of a vertically polarized antenna is greater than a space between a first sub-pattern and a third sub-pattern of a horizontally polarized antenna. FIG. 13B shows an impedance change presented on a Smith chart according to a change in a width of a first conductive pattern of a vertically polarized antenna.

Referring to FIGS. 10A, 10B and 13A, the width W1v of the first conductive pattern 1110 which is an upper-end pole of the vertically polarized antenna may be configured to be greater than the space Ga between the third sub-pattern 1150g and the feed line 1110g. Referring to the current distribution diagram, when the width W1v of the first conductive pattern 1110 is greater than the space Ga between the third sub-pattern 1150g and the feed line 1150f, very large coupling equal to or greater than a critical level occurs. The very large coupling equal to or greater than the critical level occurs in a common region R1b including a lower region of the first conductive pattern 1110 and the second sub-pattern 1150p of the loop antenna 1150 which is a horizontally polarized antenna.

Referring to FIGS. 10A, 10B, and 13B, the width W1v of the first conductive pattern 1110 may be configured to be 1 mm, which is greater than 0.9 mm, i.e., the space Ga between the third sub-pattern 1150g and the feed line 1150f. When the width W1v of the first conductive pattern 1110 is configured to be 1 mm, an impedance change for each frequency in a 60 GHz band in the Smith chart becomes very large. Thus, an antenna bandwidth becomes narrow. However, when the width W1v of the first conductive pattern 1110 is configured to be 0.2 mm or 0.6 mm, which is smaller than 0.9 mm, an impedance change for each frequency in a 60 GHz band in the Smith chart becomes small. Thus, a wide antenna bandwidth may be secured. Accordingly, the width W1v of the first conductive pattern 1110 needs to be configured to be smaller than the space Ga between the third sub-pattern 1150g and the feed line 1150f.

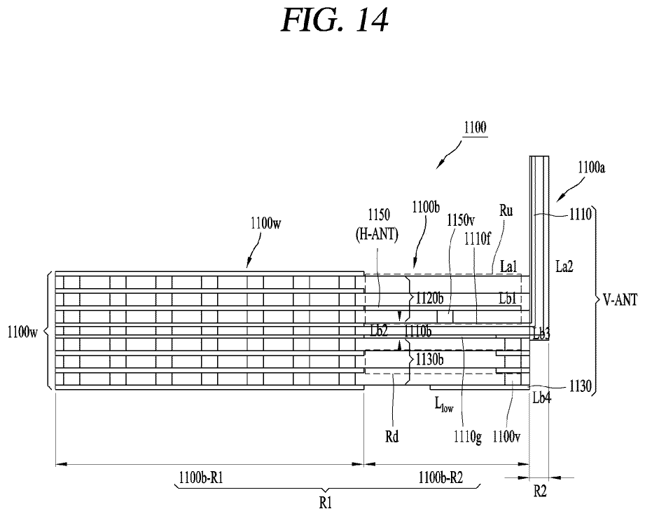

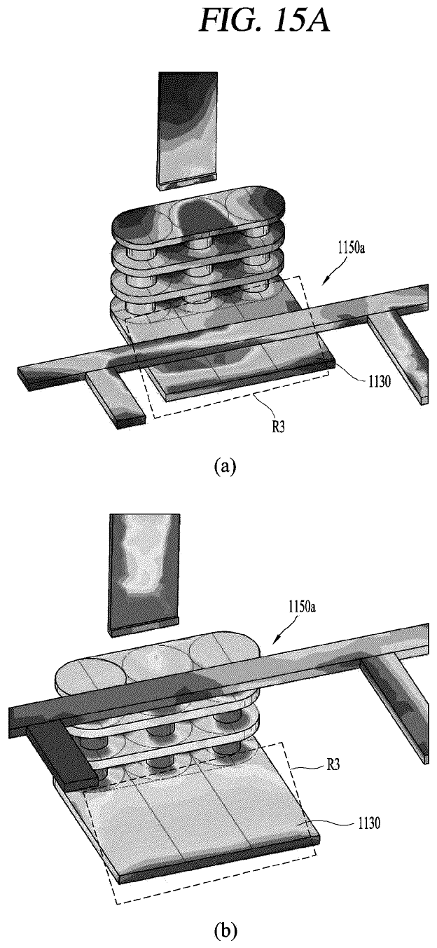

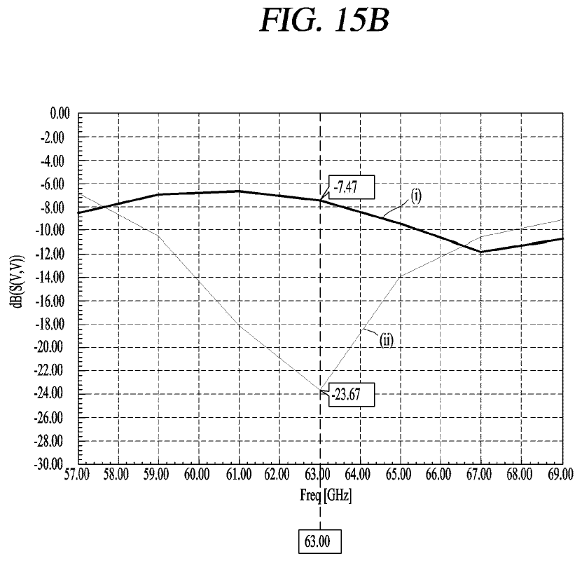

Meanwhile, in an antenna module implemented as a dual-polarized antenna according to this specification, a horizontally polarized antenna may be placed on the second layers 1120b in an upper region of the PCB 1100b or on the third layers 1130b. In this regard, FIG. 14 illustrates a structure in which a horizontally polarized antenna is capable of being placed in an upper region or a lower region of a PCB of an antenna module. FIG. 15A shows a comparison between current distribution diagrams according to structures in which a horizontally polarized antenna is arranged. FIG. 15B shows reflection coefficient characteristics according to structures in which a horizontally polarized antenna is arranged.

Referring to FIG. 7B and FIG. 14, regions Ru and Rd in which the horizontally polarized antenna H-ANT may be placed in a structure in which the vertically polarized antenna V-ANT is placed are shown. The horizontally polarized antenna H-ANT may be placed in a rear region of the first conductive pattern 1110, which is an upper-end pole of the vertically polarized antenna V-ANT. The horizontally polarized antenna H-ANT may be placed in the region Ru above the feed line 1110f of the vertically polarized antenna V-ANT. The horizontally polarized antenna H-ANT may be placed on two layers including the first sub-layer Lb1 and the second sub-layer Lb2. The feed line 1110f of the vertically polarized antenna V-ANT may be placed on the second sub-layer Lb2 of the PCB 1100b. The fourth conductive pattern 1110g corresponding to a ground line of the vertically polarized antenna V-ANT may be placed on a third sub-layer Lb3. The fifth conductive pattern 130 of the vertically polarized antenna V-ANT may be placed on a fourth sub-layer Lb4.

Referring to FIG. 14 and (a) of FIG. 15A, the horizontally polarized antenna 1150 may be placed in a lower region Rd of the PCB 1100b. When a signal is applied to the horizontally polarized antenna 1150, strong coupling occurs in a region R3 in which the fifth conductive pattern 1130 which is a lower-end pole is arranged. Thus, deterioration of performance of both the vertically polarized antenna and the horizontally polarized antenna is caused. When the horizontally polarized antenna H-ANT is placed in the lower region Rd of the fourth conductive pattern 1110g corresponding to the ground line of the vertically polarized antenna V-ANT, performance of both the vertically polarized antenna and the horizontally polarized antenna is reduced.

Referring to FIG. 7B, FIG. 14, and (b) of FIG. 15A, the horizontally polarized antenna H-ANT may be arranged in the upper region Ru of the PCB 1100b. As the horizontally polarized antenna H-ANT is placed in the upper region Ru of the PCB 1100b, when a signal is applied to the horizontally polarized antenna 1150, the coupling to the region R3 in which the fifth conductive pattern 1130 which is a lower-end pole is arranged may be reduced. Accordingly, antenna performance of the horizontally polarized antenna H-ANT and the vertically polarized antenna V-ANT may be improved.

Referring to FIGS. 14 to 15B, a change in characteristics of a reflection coefficient S11 of the vertically polarized antenna V-ANT according to structures in which the horizontally polarized antenna H-ANT is arranged is shown. In (i) a first structure in which the horizontally polarized antenna H-ANT is placed in the lower region Rd, the reflection coefficient S11 of the vertical polarized antenna V-ANT has a value of −7.5 dB at 63 GHz. On the other hand, in (ii) a second structure in which the horizontally polarized antenna H-ANT is placed in the upper region Ru, the reflection coefficient S11 of the vertical polarized antenna V-ANT may be improved to −23.7 dB by about 16.2 dB at 63 GHz. Therefore, when the FPCB 1100a is combined with a center layer of the PCB 1100b, the horizontally polarized antenna H-ANT needs to be placed in a rear region of the first conductive pattern 1110 which is an upper-end pole of the vertically polarized antenna V-ANT.

Hereinafter, an antenna module implemented as a dual-polarized antenna according to this specification will be described with reference to FIGS. 7A to 15B. The antenna module 1000 may be configured to include the FPCB 1100a and the PCB 1100b. The FPCB 1100a may include the first conductive pattern 1110 arranged on the first layer La1, and the second layer La2.

The antenna module 1000 may be constituted by the multi-layer substrates (multi-layered substrates) 1100a and 1100b made of a plurality of dielectric materials, and conductive patterns. The FPCB 1100a and the PCB 1100b may be implemented as the multi-layer substrates (multi-layered substrates). The multi-layer substrates 1100a and 1100b may be configured to include the first layer 1110b, the second layers 1120b, and the third layers 1130b.

The first layer 1110b may be made of a flexible first material. The second layers 1120b may include a plurality of layers made of a rigid second material arranged on one side surface of the first layer 1110b. The third layers 1130b may include a plurality of layers made of the rigid second material arranged on another side surface of the first layer 1110b. The first layer 1110b may be placed between the second layers 1120b and the third layers 1130b of the multi-layer substrates 1100a and 1100b.

The first layer 1110b may include the first region R1 arranged in parallel with the second layers 1120b and the third layers 1130b and the second region R2 arranged vertically to the second layers 1120b and the third layers 1130b. The first region R1 may be a PCB region and the second region R2 may be an FPCB region.

The conductive patterns may constitute a vertically polarized antenna and a horizontally polarized antenna. The first conductive pattern 1110 may be implemented as the vertically polarized antenna. The second conductive pattern 1151f and the third conductive pattern 1150 may be implemented as the horizontally polarized antenna. The second conductive pattern 1151f and the third conductive pattern 1150 may be connected to each other by the first via hole 1150v. The vertically polarized antenna may include the first conductive pattern 1110, the fourth conductive pattern 1110g, and the fifth conductive pattern 1130. The fourth conductive pattern 1110g and the fifth conductive pattern 1130 may be connected to each other by the second via hole 1100v.

The first conductive pattern 1110 may be arranged on one side surface in the first region R1 and the second region R1 of one side surface of the first layer 1110a and configured to transmit and/or receive a signal. The second conductive pattern 1151f may be arranged on the first sub-layer Lb1 which is one layer among the second layers 1120b. The third conductive pattern 1150 may be arranged on the second sub-layer Lb2, which is another layer among the second layers 1120b. The second conductive pattern 1151f and the third conductive pattern 1150 may be connected to each other through the first via hole 1150v. The first sub-layer Lb1 may be arranged to be closer to one side surface of the first layer 1110a compared to the second sub-layer Lb2. The second sub-layer Lb2 may be arranged further apart from the one side surface of the first layer 1110a compared to the first sub-layer Lb1.

The fourth conductive pattern 1110g may be arranged on the third sub-layer Lb3 which is one layer among the third layers 1130b. The fifth conductive pattern 1130 may be arranged on the fourth sub-layer Lb4 which is another layer among the third layers 1130b. The third sub-layer Lb3 may be placed to be closer to another side surface of the first layer 1110a compared to the fourth sub-layer Lb4. The fourth sub-layer Lb4 may be placed further apart from the another side surface of the first layer 1110a compared to the third sub-layer Lb3.

A region of the first conductive pattern 1110 arranged in the first region R1 of the one side surface of the first layer 1110a may be electrically connected to a first feed pattern 1110f arranged inside the multi-layer substrate in one region of the first region R1. The second conductive pattern 1151f arranged on the first sub-layer Lb1, which is one layer among the second layers 1120b, may be electrically connected to the second feed pattern 1120f placed inside the multi-layer substrate in one region of the first sub-layer Lb1. One region of a fourth conductive pattern 1140 arranged on the third sub-layer Lb3, which is one layer among the third layers 1130a, may be connected to ground of the multi-layer substrate.

A space W1v of the first conductive pattern 1110 arranged in the first region R1 may be configured to be narrower than each of spaces W1 and W2 of the fourth conductive pattern 1110g connected to the ground of the multi-layer substrate.

The third conductive pattern 1150 arranged on the second sub-layer Lb2, which is another layer among the second layers 1120b, may be constituted by the first sub-pattern 1152f, the second sub-pattern 1150p, and the third sub-pattern 1150g. The first sub-pattern 1152f may be connected to the second conductive pattern 1151f by the first via hole 1150v. One region of the third sub-pattern 1150g may be connected to the ground of the multi-layer substrate. The first sub-pattern 1152f and the third sub-pattern 1150g may be connected to each other by the second sub-pattern 1150p.

A length of the second sub-pattern 1150p may be configured to be greater than the space Ga in a gap between the first sub-pattern 1152f and the third sub-pattern 1150g. Accordingly, a horizontally polarized antenna implemented in a loop shape may be implemented as a pi (p)-shaped loop antenna. The second sub-pattern 1150p may be constituted by the pattern regions 1150p1 and 1150p2 extending, toward both sides, from two portions connected to a pattern region between the first sub-pattern 1152f and the third sub-pattern 1150g.

The first conductive pattern 1110 placed in the first region R1 of the multi-layer substrate may be arranged in a middle region between the first sub-pattern 1152f and the third sub-pattern 1150g. Accordingly, an interference level may be reduced compared to a structure in which the first conductive pattern 1110 is offset to one region among the first sub-pattern 1152f and the third sub-pattern 1150g. Therefore, an interference level between the horizontally polarized antenna and a feed pattern of the first conductive pattern 1110 operating as the vertically polarized antenna may be reduced.

The fourth conductive pattern 1110g may be constituted by the fourth sub-pattern 1111g connected to one region of the ground of the multi-layer substrate, and the fifth sub-pattern 1112g connected to second via holes 1100v. A space in the fourth sub-pattern 1111g, which is a part of the fourth conductive pattern 1110g, may be configured to be narrower than a space in the fifth conductive pattern 1130 arranged on the fourth sub-layer Lb4 among the third layers 1130b. A length of the fifth conductive pattern 1130 may be configured to be shorter than a length of the fourth sub-pattern 1111g of the fourth conductive pattern 1110g.

An end region of the fifth conductive pattern 1130 may be arranged to be electrically connected to the fifth sub-pattern 1112g by a plurality of rows 1121v to 1123v of a plurality of via holes. In this regard, the plurality of via holes 1100v arranged in the plurality of rows may be configured to include first via holes 1121v, second via holes 1122v, and third via holes 1123v.

The first conductive pattern 1110, the fourth conductive pattern 1110g, the fifth conductive pattern 1130, and the plurality of via holes 1100v may operate as antenna elements having horizontal polarization. The second conductive pattern 1151f and the third conductive pattern 1150 may operate as antenna elements having horizontal polarization.

A first height h1 of the first conductive pattern 1110 may be configured to be within a predetermined range with reference to 1 mm. A second height h2 between the fourth conductive pattern 1110g and the fifth conductive pattern 1130 of the via structure 1100v constituted by the plurality of via holes may be configured to be within a predetermined range with reference to 0.3 mm. The fifth conductive pattern 1130 arranged on a lowest layer may be connected to the fourth conductive pattern 1110g of the PCB 1100b through the via structure 1100v.

As described above, the fourth sub-pattern 1111g of the fourth conductive pattern 1110g may be configured to have a first width W1. The fifth sub-pattern 1112g of the fourth conductive pattern 1110g may be configured to have a second width W2 greater than the first width W1. The via structure 1100v may include the plurality of via holes spaced apart from each other in a first axial direction to connect the fourth sub-pattern 1111g to the fifth conductive pattern 1130 in the first axial direction. In this regard, the plurality of via holes 1100v arranged in the plurality of rows may be configured to include the first via holes 1121v, the second via holes 1122v, and the third via holes 1123v. The second width of the fifth sub-pattern 1112g in which the first to third via holes 1121v, 1122v, and 1123v are arranged may be configured to be in a range between 0.2 mm and 1.0 mm.

According to this specification, a vertically polarized dipole antenna structure may be presented using the FPCB 1100a vertical to an end portion at one side of the PCB 1100b. In this regard, one pole may be arranged on one layer of the FPCB 1100a, and another pole may be arranged on the PCB. An electric field having vertical polarization may be generated by upper and lower-end poles to operate as a vertically polarized antenna. Meanwhile, a pi loop antenna operating in horizontal polarization may be implemented on another layer of the PCB 1100b to radiate electric field components of the horizontal polarization.

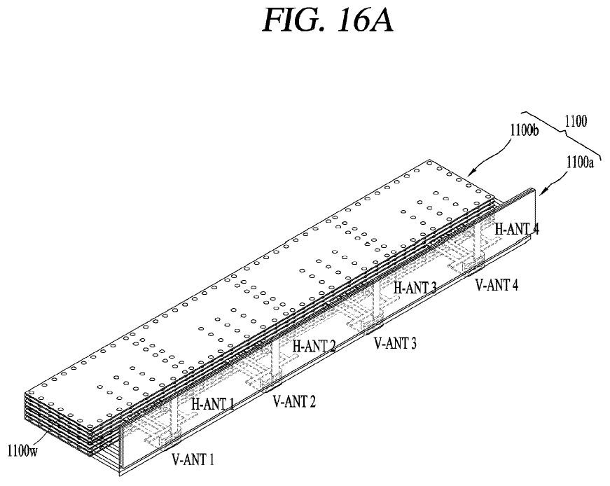

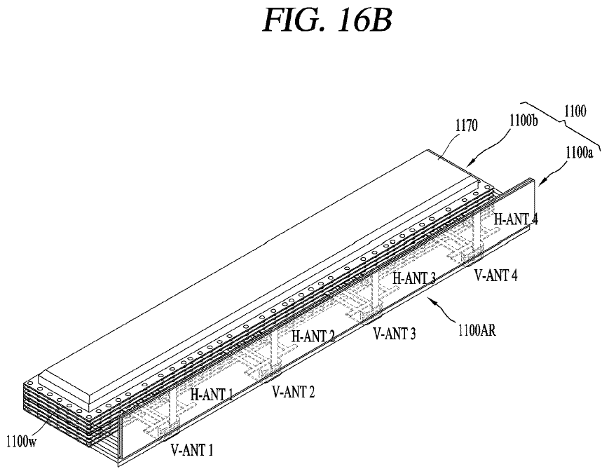

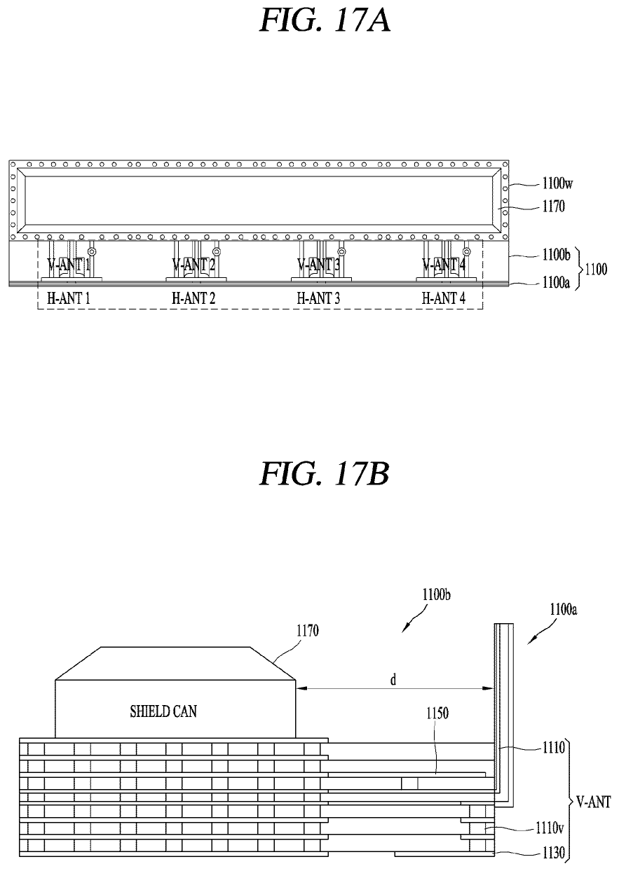

Meanwhile, an antenna module implemented as a dual-polarized antenna according to this specification may be implemented as an array antenna. In this regard, FIG. 16A illustrates an antenna module implemented as a dual-polarized array antenna according to an embodiment. FIG. 16B illustrates a structure in which a shield can is arranged on top of a PCB of the antenna module of FIG. 16A. Meanwhile, FIG. 17A is a front view of an array antenna module in which the shield can of FIG. 16B is arranged. FIG. 17B is a side view of the array antenna module in which the shield can of FIG. 17A is arranged.

Referring to FIGS. 16A to 17B, a shield can 1170 may be placed on an upper portion of the PCB 1100b on which a 1×4 dual-polarized end-fire array antenna is implemented. The shield can 1170 may be implemented as a metal case, but is not limited thereto. An array antenna gain may be improved using components mounted on the PCB 1110b of the dual-polarized end-fire array antenna.

For example, when it is assumed that a component mounted on the PCB 1110b is the shield can 1170, the shield can 1170 may be arranged on the upper portion of the PCB 1110b. The shield can 1170 may be attached to the ground wall 1100w of the PCB 1100b, and the dual-polarized end-fire array antenna may be placed in a front portion of the shield can 1170. An antenna gain of the array antenna varies depending on a distance d between the shield can 1170 and an antenna. Here, d may be defined as a distance from the shield can 1170 to the first conductive pattern 1100 of the vertically polarized antenna arranged on the FPCB.

A plurality of antenna elements may be arranged in a first axial direction to constitute an array antenna 1100AR. A first horizontally polarized antenna element H-ANT1 to a fourth horizontally polarized antenna element H-ANT4 of the array antenna 1100AR may be configured to radiate a beamformed first wireless signal having horizontal polarization in a first axial direction. A first vertically polarized antenna element V-ANT1 to a fourth vertically polarized antenna element V-ANT1 of the array antenna 1100AR may be configured to radiate a beamformed second wireless signal having vertical polarization in the first axial direction.

The antenna module 1100 may further include the shield can 1170 arranged on a ground pattern in an upper portion of the ground wall 1100w arranged in an inner region of the PCB 1100b. The distance d between the shield can 1170 and the first conductive pattern 1110 arranged on the FPCB 1100a may be configured to be in a range of (0.17+n)*λ₀<d<(0.33+n)*λ₀. Here, n may be 0 or a natural number.

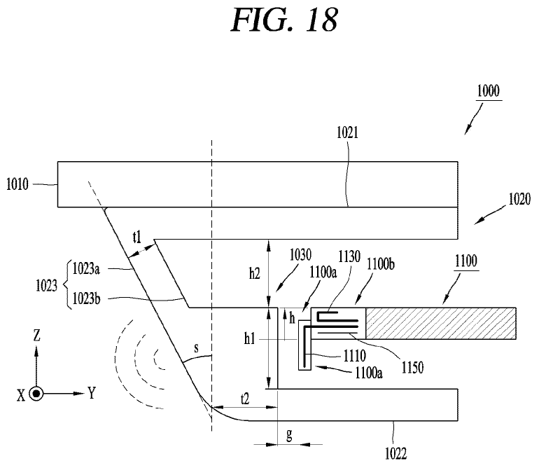

An antenna module implemented as a dual-polarized antenna according to one aspect of this specification has been described above. Hereinafter, an electronic device having an antenna module implemented as a dual-polarized antenna according to another aspect of this specification is to be described. In this regard, all the technical features and configurations described above also apply to a description to be provided hereinafter. FIG. 18 illustrates an electronic device having an antenna module arranged in a dielectric case according to this specification.

Referring to FIG. 18, an antenna module 1000 may be placed inside a mechanical structure such as a dielectric case 1020 of a metal frame 1010 of the electronic device having a display. In this regard, a rear surface of the PCB 1100b of the antenna module 1000 may be placed to face the metal frame 1010 so that a rear surface of the antenna module 1000 is directed toward the metal frame 1010.

To minimize an interference of the metal frame 1010, it is advantageous for the first conductive pattern 1110 which is an upper-end pole to be directed toward an opposite direction to the metal frame 1010, that is, toward a lower end. Accordingly, the fifth conductive pattern 1130, which is an inverted C-shaped lower-end pole, may be placed to be adjacent to the metal frame 1010.

Referring to FIGS. 1 to 18, the electronic device 1000 may be configured to include the metal frame 1010, the dielectric case 1020, and the antenna module 1100. The metal frame 1010 may be configured to constitute a side surface region of the electronic device 1000. The metal frame 1010 may be arranged to surround the display and configured to support the display. The dielectric case 1020 may be located on one side of the metal frame 1010. The dielectric case 1020 may be arranged on one side surface constituting a lower region of the metal frame 1010.

The antenna module 1100 may be arranged in an inner region of the dielectric case 1020. The antenna module 1100 may be arranged to face an inner surface 1023 of the dielectric case 1020. The dielectric case 1020 may include a front surface portion 1021 attached to the metal frame 1020, a rear surface portion 1022 corresponding to the front surface portion 1021, and a side surface portion 1023 arranged between the front surface portion 1021 and the rear surface portion 1022. The antenna module 1000 may be configured to include the FPCB 1100a and the PCB 1100b.

The antenna module 1000 may be constituted by the multi-layer substrates (multi-layered substrates) 1100a and 1100b made of a plurality of dielectric materials, and conductive patterns. The FPCB 1100a and the PCB 1100b may be implemented as the multi-layer substrates (multi-layered substrates). The multi-layer substrates 1100a and 1100b may be configured to include the first layer 1110b, the second layers 1120b, and the third layers 1130b.

The first layer 1110b may be made of a flexible first material. The second layers 1120b may include a plurality of layers made of a rigid second material arranged on one side surface of the first layer 1110b. The third layers 1130b may include a plurality of layers made of the rigid second material arranged on another side surface of the first layer 1110b. The first layer 1110b may be placed between the second layers 1120b and the third layers 1130b of the multi-layer substrates 1100a and 1100b.

The first layer 1110b may include the first region R1 arranged in parallel with the second layers 1120b and the third layers 1130b and the second region R2 arranged vertically to the second layers 1120b and the third layers 1130b. The first region R1 may be a PCB region and the second region R2 may be an FPCB region.

The conductive patterns may constitute a vertically polarized antenna and a horizontally polarized antenna. The first conductive pattern 1110 may be implemented as the vertically polarized antenna. The second conductive pattern 1151f and the third conductive pattern 1150 may be implemented as the horizontally polarized antenna. The second conductive pattern 1151f and the third conductive pattern 1150 may be connected to each other by the first via hole 1150v. The vertically polarized antenna may include the first conductive pattern 1110, the fourth conductive pattern 1110g, and the fifth conductive pattern 1130. The fourth conductive pattern 1110g and the fifth conductive pattern 1130 may be connected to each other by the second via hole 1100v.

The first conductive pattern 1110 may be arranged on one side surface in the first region R1 and the second region R1 of one side surface of the first layer 1110a and configured to transmit and/or receive a signal. The second conductive pattern 1151f may be arranged on the first sub-layer Lb1 which is one layer among the second layers 1120b. The third conductive pattern 1150 may be arranged on the second sub-layer Lb2, which is another layer among the second layers 1120b. The second conductive pattern 1151f and the third conductive pattern 1150 may be connected to each other through the first via hole 1150v. The first sub-layer Lb1 may be arranged to be closer to one side surface of the first layer 1110a compared to the second sub-layer Lb2. The second sub-layer Lb2 may be arranged further apart from one side surface of the first layer 1110a compared to the first sub-layer Lb1.

The fourth conductive pattern 1110g may be arranged on the third sub-layer Lb3 which is one layer among the third layers 1130b. The fifth conductive pattern 1130 may be arranged on the fourth sub-layer Lb4, which is another layer among the third layers 1130b. The third sub-layer Lb3 may be placed to be closer to another side surface of the first layer 1110a compared to the fourth sub-layer Lb4. The fourth sub-layer Lb4 may be placed further apart from the another side surface of the first layer 1110a compared to the third sub-layer Lb3.

A region of the first conductive pattern 1110 arranged in the first region R1 of the one side surface of the first layer 1110a may be electrically connected to the first feed pattern 1110f arranged inside the multi-layer substrate in one region of the first region R1. The second conductive pattern 1151f arranged on the first sub-layer Lb1, which is one layer among the second layers 1120b, may be electrically connected to the second feed pattern 1120f placed inside the multi-layer substrate in one region of the first sub-layer Lb1. One region of the fourth conductive pattern 1140 arranged on the third sub-layer Lb3, which is one layer among the third layers 1130a, may be connected to ground of the multi-layer substrate.

The space W1v of the first conductive pattern 1110 arranged in the first region R1 may be configured to be narrower than each of the spaces W1 and W2 of the fourth conductive pattern 1110g connected to the ground of the multi-layer substrate.

The third conductive pattern 1150 arranged on the second sub-layer Lb2, which is another layer among the second layers 1120b, may be constituted by the first sub-pattern 1152f, the second sub-pattern 1150p, and the third sub-pattern 1150g. The first sub-pattern 1152f may be connected to the second conductive pattern 1151f by the first via hole 1150v. One region of the third sub-pattern 1150g may be connected to the ground of the multi-layer substrate. The first sub-pattern 1152f and the third sub-pattern 1150g may be connected to each other by the second sub-pattern 1150p.

A length of the second sub-pattern 1150p may be configured to be greater than the space Ga in a gap between the first sub-pattern 1152f and the third sub-pattern 1150g. Accordingly, a horizontally polarized antenna implemented in a loop shape may be implemented as a pi (p)-shaped loop antenna. The second sub-pattern 1150p may be constituted by the pattern regions 1150p1 and 1150p2 extending, toward both sides, from two portions connected to a pattern region between the first sub-pattern 1152f and the third sub-pattern 1150g.

The first conductive pattern 1110 placed in the first region R1 of the multi-layer substrate may be arranged in a middle region between the first sub-pattern 1152f and the third sub-pattern 1150g. Accordingly, an interference level may be reduced compared to a structure in which the first conductive pattern 1110 is offset to one region among the first sub-pattern 1152f and the third sub-pattern 1150g. Therefore, an interference level between the horizontally polarized antenna and a feed pattern of the first conductive pattern 1110 operating as the vertically polarized antenna may be reduced.

The fourth conductive pattern 1110g may be constituted by the fourth sub-pattern 1111g connected to one region of the ground of the multi-layer substrate, and the fifth sub-pattern 1112g connected to the second via holes 1100v. A space in the fourth sub-pattern 1111g, which is a part of the fourth conductive pattern 1110g, may be configured to be narrower than a space in the fifth conductive pattern 1130 arranged on the fourth sub-layer Lb4 among the third layers 1130b. A length of the fifth conductive pattern 1130 may be configured to be shorter than a length of the fourth sub-pattern 1111g of the fourth conductive pattern 1110g.

An end region of the fifth conductive pattern 1130 may be arranged to be electrically connected to the fifth sub-pattern 1112g by the plurality of rows 1121v to 1123v of a plurality of via holes. In this regard, the plurality of via holes 1100v arranged in the plurality of rows may be configured to include the first via holes 1121v, the second via holes 1122v, and the third via holes 1123v.

The first conductive pattern 1110, the fourth conductive pattern 1110g, the fifth conductive pattern 1130, and the plurality of via holes 1100v may operate as antenna elements having horizontal polarization. The second conductive pattern 1151f and the third conductive pattern 1150 may operate as antenna elements having horizontal polarization.

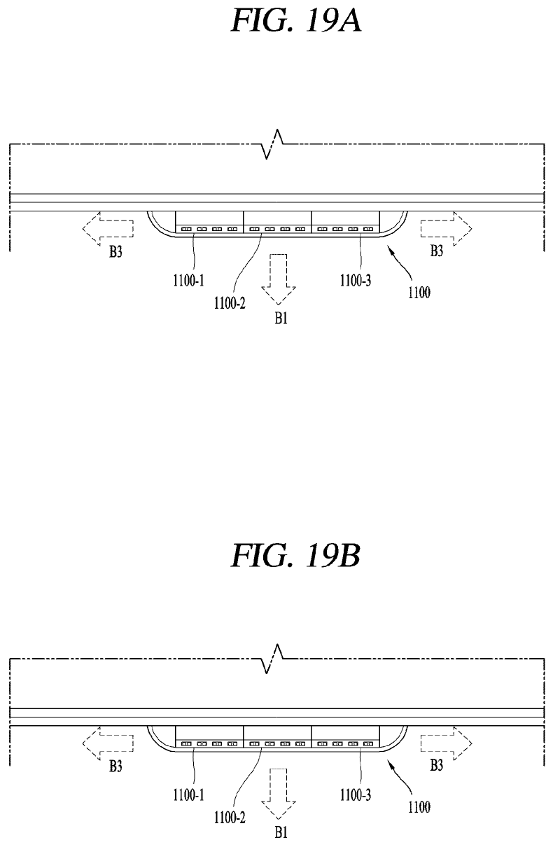

An antenna module implemented as a dual-polarized antenna disclosed herein may be configured as an array antenna in an electronic device. In this regard, FIG. 19A illustrates a structure in which an antenna module constituted by a plurality of array antennas is arranged in an electronic device. FIG. 19B is an enlarged view of the plurality of array antenna modules of FIG. 19A.

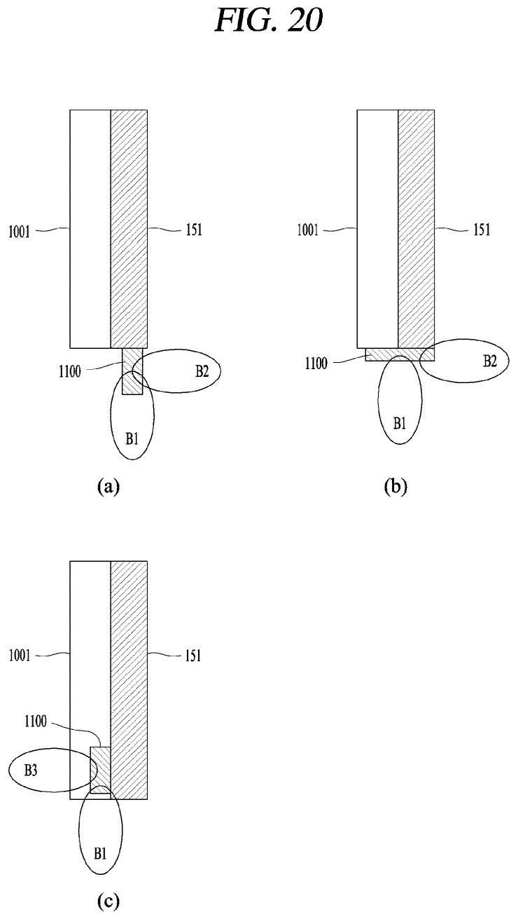

Referring to FIGS. 1 to 19B, an array antenna may include the first antenna module 1100-1 and the second antenna module 1100-2 arranged apart from the first antenna module 1100-1 by a predetermined space in a first horizontal direction. Meanwhile, antenna modules are not limited to two antenna modules. Three or more antenna modules may be implemented as illustrated in FIG. 20B. Accordingly, the antenna modules may be configured to include first to third antenna modules 1100-1 to 1100-3.

The processor 1400 of FIGS. 5 to 6C may control to generate a first beam and a second beam in a first direction and a second direction using the first and second antenna modules 1100-1 and 1100-2, respectively. That is, the first beam may be generated from a horizontal direction toward the first direction using the first antenna module 1100-1. In addition, the second beam may be generated from a horizontal direction toward the second direction using the second antenna module 1100-2. In relation to this, the processor 1400 may perform MIMO using the first beam in the first direction and the second beam in the second direction.

The processor 1400 may generate a third beam in a third direction using the first and second antenna modules 1100-1 and 1100-2. In relation to this, the processor 1400 may control the transceiver circuit 1250 to synthesize signals received through the first and second antenna modules 1100-1 and 1100-2. Also, the processor 1400 may control signals transmitted to the first and second antenna modules 1100-1 and 1100-2 through the transceiver circuit 1250 to be distributed to each antenna element. The processor 1400 may perform beamforming using the third beam having a beam width smaller than each of beam widths of the first beam and the second beam.

Meanwhile, the processor 1400 may perform MIMO using the first beam in the first direction and the second beam in the second direction, and perform beamforming using the third beam having a beam width smaller than each of beam widths of the first and second beams. In relation to this, when quality of a first signal and a second signal received from another electronic device in a periphery of the electronic device is equal to or less than a threshold, beamforming may be performed using the third beam.

A number of elements of the array antenna is not limited to two, three, four, or the like as illustrated in the drawing. For example, the number of the elements of the array antenna may extend to 2, 4, 8, 16, or the like. Accordingly, the array antenna may be configured as a 1×2, 1×3, 1×4, 1×5, . . . , 1×8 array antenna.

Meanwhile, FIG. 20 illustrates an antenna module combined in varying combination structures at a particular position in an electronic device according to embodiments. Referring to (a) of FIG. 20, the antenna module 1100 may be arranged on a lower region of the display 151 to be substantially horizontal to the display 151. Accordingly, a beam B1 may be generated in a lower direction of the electronic device through one array antenna among a plurality of array antenna modules. Meanwhile, another beam B2 may be generated in a front direction of the electronic device through another array antenna among the plurality of array antenna modules.

Referring to (b) of FIG. 20, the array antenna module 1100 may be arranged on a lower region of the display 151 to be substantially vertical to the display 151. Accordingly, a beam B2 may be generated in a front direction of the electronic device through one array antenna among the plurality of array antenna modules. Meanwhile, another beam B1 may be generated in a lower direction of the electronic device through another array antenna among the plurality of array antenna modules.

Referring to (c) of FIG. 20, the antenna module 1100 may be arranged in a rear case 1001 corresponding to a mechanical structure. The antenna module 1100 may be arranged in the rear case 1001 to be substantially in parallel with the display 151. Accordingly, a beam B1 may be generated in a lower direction of the electronic device through one array antenna among a plurality of array antenna modules. Meanwhile, another beam B3 may be generated in a rear direction of the electronic device through another array antenna among the plurality of array antenna modules.

The antenna module implemented as a dual-polarized antenna, and the electronic device including the antenna module have been described above. Hereinafter, technical effects of the antenna module implemented as a dual-polarized antenna according to this specification and the electronic device including the antenna module are to be described.

According to an embodiment, an antenna module in which a dual-polarized antenna operating in a mm Wave band is implemented, and an electronic device including the antenna module may be provided.

According to an embodiment, an antenna may be implemented on one side of a PCB to perform radiation through a conductive pattern of an FPCB and a via structure and a conductive pattern implemented on one side of the PCB.

According to an embodiment, a dual-polarized end-fire antenna may be provided such that a dual-polarized antenna operating as a horizontally polarized antenna and a vertically polarized antenna performs radiation through one side of a PCB.

According to an embodiment, a vertically polarized antenna may be provided through an asymmetrical dipole antenna constituted by an upper-end pole and a lower-end pole arranged on an FPCB and a PCB, respectively.

According to an embodiment, vertical polarization may be implemented even at a height of a PCB which is insufficient to implement the vertical polarization by arranging an FPCB vertically to the PCB and through a conductive pattern of the FPCB and a conductive pattern and a vertical via of the PCB.

According to an embodiment, radiation performance may be enhanced by increasing an area by implementing one pole on an FPCB and another pole on a PCB as radiators to thereby improve performance of vertical polarization.

According to an embodiment, an area occupied by antennas in a limited substrate region may be minimized by arranging a vertically polarized antenna and a horizontally polarized antenna in an overlapping region.

According to an embodiment, wireless communication may be performed with a peripheral electronic device by optimally arranging an antenna module on a lower portion of an electronic device.

Further scope of applicability of this specification will become apparent from the following detailed description. It should be understood, however, that the detailed description and specific examples, such as the preferred embodiment of the disclosure, are given by way of illustration only, since various changes and modifications within the spirit and scope of the disclosure will be apparent to those skilled in the art. In relation to this specification described above, designing and driving of an antenna operating in a mmWave band and an electronic device controlling the antenna may be implemented as computer-readable codes on a medium having a program recorded thereon.

The computer-readable medium includes all kinds of recording devices in which data readable by a computer system is stored. Examples of the computer-readable medium include a hard disk drive (HDD), a solid state disk (SSD), a silicon disk drive (SDD), a ROM, a RAM, a CD-ROM, a magnetic tape, a floppy disk, an optical data storage device and the like, and may also be implemented in the form of a carrier wave (e.g., transmission over the Internet). The computer may include the control unit of the terminal. Therefore, it should also be understood that the above-described embodiments are not limited by any of the details of the foregoing description, unless otherwise specified, but rather should be construed broadly within its scope as defined in the appended claims, The scope of this specification should be determined by reasonable interpretation of the appended claims, and all changes within the scope of equivalents of this specification are included in the scope of this specification.

1. An antenna module comprising a multi-layer substrate made of a plurality of dielectric materials and a conductive pattern,
wherein the multi-layer substrate comprises:
a first layer made of a flexible first material;
second layers comprising a plurality of layers made of a rigid second material arranged on one side surface of the first layer; and
third layers comprising a plurality of layers made of the rigid second material arranged on another side surface of the first layer, and
the first layer comprises a first region arranged in parallel with the second layers and the third layers, and a second region arranged to be vertical to the second layers and the third layers,
a first conductive pattern is arranged on the one side surface in the first region and the second region of the one side surface of the first layer to transmit and receive a signal,
a second conductive pattern arranged on a first sub-layer, which is one layer among the second layers, and a third conductive pattern arranged on a second sub-layer, which is another layer among the second layers, are connected to each other through a first via hole,
the first sub-layer is arranged close to the one side surface of the first layer, and the second sub-layer is arranged further apart from the one side surface of the first layer compared to the first sub-layer,
a fourth conductive pattern arranged on a third sub-layer, which is one layer among the third layers, and a fifth conductive pattern arranged on a fourth sub-layer, which is another layer among the third layers, are connected to each other through second via holes, and
the third sub-layer is arranged close to the another side surface of the first layer, and the fourth sub-layer is arranged further apart from the another side surface of the first layer compared to the third sub-layer.

2. The antenna module of claim 1, wherein a region of the first conductive pattern arranged in the first region of the one side surface of the first layer is electrically connected to a first feed pattern arranged inside the substrate in one region of the first region,
the second conductive pattern arranged on the first sub-layer, which is one layer among the second layers, is electrically connected to a second feed pattern arranged inside the substrate in one region of the first sub-layer, and
one region of the fourth conductive pattern arranged on the third sub-layer, which is one layer among the third layers, is connected to ground of the multi-layer substrate.

3. The antenna module of claim 2, wherein a space in the first conductive pattern arranged in the first region is narrower than a space in the fourth conductive pattern connected to the ground of the multi-layer substrate.

4. The antenna module of claim 2, wherein the third conductive pattern arranged on the second sub-layer, which is another layer among the second layers, comprises a first sub-pattern, a second sub-pattern, and a third sub-pattern,
the first sub-pattern is connected to the second conductive pattern through the first via hole,
one region of the third sub-pattern is connected to the ground of the substrate, and
the first sub-pattern and the third sub-pattern are connected to each other by the second sub-pattern.

5. The antenna module of claim 4, wherein a length of the second sub-pattern is configured to be greater than a space in a gap between the first sub-pattern and the third sub-pattern.

6. The antenna module of claim 5, wherein the second sub-pattern comprises pattern regions extending, toward both sides, from two portions connected to a pattern region between the first sub-pattern and the third sub-pattern.

7. The antenna module of claim 4, wherein the first conductive pattern located in the first region is arranged in a middle region between the first sub-pattern and the third sub-pattern.

8. The antenna module of claim 1, wherein the fourth conductive pattern comprises a fourth sub-pattern connected to one region of the ground of the multi-layer substrate and a fifth sub-pattern connected to the second via holes, and
a space in the fourth sub-pattern, which is a part of the fourth conductive pattern, is narrower than a space in the fifth conductive pattern arranged in the fourth sub-layer among the third layers.

9. The antenna module of claim 8, wherein a length of the fifth conductive pattern is shorter than a length of the fourth sub-pattern of the fourth conductive pattern.

10. The antenna module of claim 8, wherein one end region of the fifth conductive pattern is configured to be electrically connected to the fifth sub-pattern through a plurality of rows of a plurality of via holes.

11. The antenna module of claim 10, wherein the first conductive pattern, the fourth conductive pattern, the fifth conductive pattern, and the plurality of via holes operate as antenna elements having vertical polarization, and
the second conductive pattern and the third conductive pattern operate as antenna elements having horizontal polarization.

12. The antenna module of claim 11, wherein a first height of the third conductive pattern is configured to be within a predetermined range with reference to 1 mm, and
a second height between the fourth conductive pattern and the fifth conductive pattern of a via structure implemented by the plurality of via holes is configured to be within a predetermined range with reference to 0.3 mm.

13. The antenna module of claim 12, wherein the fourth sub-pattern of the fourth conductive pattern is configured to have a first width, and the fifth sub-pattern of the fourth conductive pattern is configured to have a second width greater than the first width,
the via structure comprises a plurality of via holes arranged to be spaced apart from each other by a predetermined space to connect the fourth sub-pattern to the fifth conductive pattern in a first axial direction, and
the second width of the fifth sub-pattern is configured to be in a range between 0.2 mm and 1.0 mm.

14. The antenna module of claim 13, wherein the antenna elements are arranged in plurality in the first axial direction to constitute an array antenna,
a first horizontally polarized antenna element to a fourth horizontally polarized antenna element of the array antenna are configured to radiate a beamformed first wireless signal having horizontal polarization in the first axial direction, and
a first vertically polarized antenna element to a fourth vertically polarized antenna element of the array antenna are configured to radiate a beamformed second wireless signal having vertical polarization in the first axial direction.

15. The antenna module of claim 14, further comprising a shield can arranged on a ground pattern in an upper portion of a ground wall arranged in an inner region of a printed circuit board (PCB) of the multi-layer substrate, and
a distance d from the shield can to the third conductive pattern arranged on a flexible printed circuit board (FPCB) is arranged in a range of (0.17+n)*λ₀ <d<(0.33+n)*λ₀.

16. An electronic device having an antenna module, the electronic device comprising:
a metal frame constituting a side region of the electronic device;
a dielectric case arranged on one side of the metal frame; and
an antenna module arranged in an inner region of the dielectric case, arranged to face an inner surface of the dielectric case, and comprising a multi-layer substrate made of a plurality of dielectric materials and a conductive pattern,
wherein the multi-layer substrate comprises:
a first layer made of a flexible first material;
second layers comprising a plurality of layers made of a rigid second material arranged on one side surface of the first layer; and
third layers comprising a plurality of layers made of the rigid second material arranged on another side surface of the first layer,
wherein the first layer comprises a first region arranged in parallel with the second layers and the third layers, and a second region arranged to be vertical to the second layers and the third layers,
a first conductive pattern is arranged on the one side surface in the first region and the second region of the one side surface of the first layer to transmit and receive a signal,
a second conductive pattern arranged on a first sub-layer, which is one layer among the second layers, and a third conductive pattern arranged on a second sub-layer, which is another layer among the second layers, are connected to each other through a first via hole,
the first sub-layer is arranged to be close to the one side surface of the first layer, and the second sub-layer is arranged further apart from the one side surface of the first layer compared to the first sub-layer,
a fourth conductive pattern arranged on a third sub-layer, which is one layer among the third layers, and a fifth conductive pattern arranged on a fourth sub-layer, which is another layer among the third layers, are connected to each other through second via holes, and
the third sub-layer is arranged close to the another side surface of the first layer, and the fourth sub-layer is arranged further apart from the another side surface of the first layer compared to the third sub-layer.

17. The electronic device of claim 16, wherein a region of the first conductive pattern arranged in the first region of the one side surface of the first layer is electrically connected to a first feed pattern arranged inside the substrate in one region of the first region,
the second conductive pattern arranged on the first sub-layer, which is one layer among the second layers, is electrically connected to a second feed pattern arranged inside the substrate in one region of the first sub-layer, and
one region of the fourth conductive pattern arranged on the third sub-layer, which is one layer among the third layers, is connected to ground of the multi-layer substrate.

18. The electronic device of claim 17, wherein a space in the first conductive pattern arranged in the first region is narrower than a space in the fourth conductive pattern connected to the ground of the multi-layer substrate.

19. The electronic device of claim 17, wherein the third conductive pattern arranged on the second sub-layer, which is another layer among the second layers, comprises a first sub-pattern, a second sub-pattern, and a third sub-pattern,
the first sub-pattern is connected to the second sub-pattern through the first via hole,
one region of the third sub-pattern is connected to the ground of the substrate, and
the first sub-pattern and the third sub-pattern are connected to each other by the second sub-pattern.

20. The electronic device of claim 19, wherein a length of the second sub-pattern is configured to be greater than a space in a gap between the first sub-pattern and the third sub-pattern.
